(19) United States
(12) Patent Application Publication
(10) Pub. No.: US 2024/0178345 A1
(43) Pub. Date: May 30, 2024

(54) LIGHT-EMITTING DEVICE, DISPLAY APPARATUS INCLUDING THE SAME AND METHOD FOR MANUFACTURING THE SAME

(71) Applicant: LG DISPLAY CO., LTD., Seoul (KR)

(72) Inventors: Hyowon KWON, Paju-si (KR); Il-Soo KIM, Paju-si (KR)

(73) Assignee: LG DISPLAY CO., LTD., Seoul (KR)

(21) Appl. No.: 18/367,184

(22) Filed: Sep. 12, 2023

(30) Foreign Application Priority Data
Nov. 25, 2022 (KR) 10-2022-0160206

(51) Int. Cl. H01L 33/24; H01L 25/075; H01L 33/00; H01L 33/32; H01L 33/44; H01L 33/62

(52) U.S. Cl. CPC H01L 33/24; H01L 25/0753; H01L 33/007; H01L 33/0093; H01L 33/32; H01L 33/44; H01L 33/62; H01L 2933/0025; H01L 2933/0066; H01L 2933/0091

(57) ABSTRACT

A display apparatus includes a package substrate in which a plurality of circuit elements are disposed, wherein the package substrate includes a holder area; and a light-emitting device, wherein the light-emitting device includes: a nitride semiconductor structure including a first semiconductor layer, an active layer, and a second semiconductor layer disposed sequentially; and a passivation pattern disposed on an outer surface of the nitride semiconductor structure, wherein the first semiconductor layer includes a protrusion, the protrusion protrudes in a direction away from the active layer, wherein the protrusion is disposed in the holder area.

### CROSS-REFERENCE TO RELATED APPLICATION

This application claims priority from Korean Patent Application No. 10-2022-0160206 filed on Nov. 25, 2022, which is hereby incorporated by reference in its entirety.

### BACKGROUND

### Field of the Disclosure

The present disclosure relates to a light-emitting device, and more particularly, to a light-emitting device including a structure capable of preventing damage to the light-emitting device, a display apparatus including the light-emitting device, and a method for manufacturing the display apparatus.

### Description of the Background

A display apparatus has been applied to various electronic devices such as TVs, mobile phones, laptops and tablets. Among display apparatuses, a light-emitting display apparatus has a light-emitting element or a light source built therein and displays information using light generated from the built-in light-emitting element or light source. A display apparatus including a self-light-emitting element may be implemented to be thinner than a display apparatus with the built-in light source, and may be implemented as a flexible display apparatus that may be folded, bent, or rolled.

The display apparatus having the self-light-emitting element may include, for example, an organic light-emitting display apparatus (OLED) including a light-emitting layer made of an organic material, or a micro-LED display apparatus (micro light-emitting diode display apparatus) including a light-emitting layer made of an inorganic material. In this regard, the organic light-emitting display apparatus does not require a separate light source. However, due to material characteristics of the organic material that is vulnerable to moisture and oxygen, a defective pixel may easily occur in the organic light-emitting display apparatus through external environment.

On the contrary, the micro-LED display apparatus includes the light-emitting layer made of the inorganic material that is resistant to moisture and oxygen and thus may not be affected by the external environment and thus may provide good reliability and has a long lifespan compared to the organic light-emitting display apparatus.

Further, the micro-LED display apparatus may be resistant to the external environment, and thus may not require a protective structure such as a sealing material, and various types of materials may be used as a material of a substrate of the apparatus. Thus, the micro-LED display apparatus may be made of being thinner than the organic light-emitting display apparatus and may be more advantageous in being implemented as a flexible display apparatus.

Further, a plurality of micro-LEDs can be connected to each other to implement a large-area display apparatus. Thus, the micro-LED display apparatus is in the limelight as a next-generation display apparatus.

Accordingly, research is being conducted to improve the characteristics of the micro-LED display apparatus while increasing light-emitting efficiency of the micro-LED display apparatus.

### SUMMARY

Accordingly, the present disclosure is directed to a light-emitting device, a display apparatus including the same and a method for manufacturing the same that substantially obviate one or more of problems due to limitations and disadvantages described above.

More specifically, the present disclosure is to provide a light-emitting device capable of preventing deterioration of characteristics of a light-emitting device chip due to crack defects or the like occurring in a laser lift-off process.

The present disclosure is also to reduce a contact area between a nitride semiconductor structure and a growth substrate to provide a relatively thick passivation pattern, thereby protecting a side surface of the nitride semiconductor structure, and thus compensating for decrease in external quantum efficiency.

Also, the present disclosure is to reduce the contact area between the nitride semiconductor structure and the growth substrate to reduce a space margin between adjacent light-emitting device chips, thereby increasing a density of the light-emitting device chips and thus improving a yield and optimizing a process.

Further, the present disclosure is to provide a display apparatus and a method for manufacturing the same in which each of the plurality of light-emitting device chips is fixed to the package substrate while a bottom protrusion of a nitride semiconductor structure is inserted into a holder area of the package substrate in bonding the plurality of light-emitting device chips to the package substrate, and thus misalignment of the plurality of light-emitting device chips is prevented.

The present disclosure is not limited to the above-mentioned features. Other features and advantages according to the present disclosure that are not mentioned may be understood based on following descriptions, and may be more clearly understood based on aspects according to the present disclosure. Further, it will be easily understood that the purposes and advantages according to the present disclosure may be realized using means shown in the claims or combinations thereof.

In an aspect of the present disclosure, a light-emitting device includes a nitride semiconductor structure including a first semiconductor layer, an active layer and a second semiconductor layer disposed sequentially; and a passivation pattern disposed on an outer surface of the nitride semiconductor structure, wherein the first semiconductor layer includes a protrusion, the protrusion protrudes in a direction away from the active layer.

In another aspect of the present disclosure, a display apparatus includes a package substrate in which a plurality of circuit elements are disposed, wherein the package substrate includes a holder area; and a light-emitting device, wherein the light-emitting device includes: a nitride semiconductor structure including a first semiconductor layer, an active layer, and a second semiconductor layer disposed sequentially; and a passivation pattern disposed on an outer surface of the nitride semiconductor structure, wherein the first semiconductor layer includes a protrusion, the protrusion protrudes in a direction away from the active layer, wherein the protrusion is disposed in the holder area.

In yet another aspect of the present disclosure, a display apparatus includes a package substrate in which a plurality of circuit elements are disposed; and a light-emitting device, wherein the light-emitting device includes: a nitride semiconductor structure including a first semiconductor layer, an active layer, and a second semiconductor layer disposed sequentially; and a passivation pattern disposed on an outer surface of the nitride semiconductor structure, wherein the light-emitting device and the package substrate are bonded to each other via a conductive adhesive material.

In still another aspect of the present disclosure, a method for manufacturing a display apparatus, the method includes providing a light-emitting device, wherein the light-emitting device includes a nitride semiconductor structure, and a passivation pattern disposed on an outer surface of the nitride semiconductor structure, wherein the nitride semiconductor structure includes a first semiconductor layer, an active layer and a second semiconductor layer disposed sequentially, wherein the first semiconductor layer includes a lower portion and an upper portion with a width larger than that of the lower portion; providing a package substrate having a holder area defined therein with which the light-emitting device are aligned, wherein a plurality of circuit elements for driving the light-emitting device is disposed in the package substrate; placing the lower portion of the first semiconductor layer into the holder area; and bonding the package substrate and the light-emitting device to each other.

In a further aspect of the present disclosure, a light-emitting device includes a first semiconductor layer, an active layer and a second semiconductor layer disposed sequentially; and a passivation pattern disposed on an outer surface of the first semiconductor layer, the active layer and the second semiconductor layer, wherein the first semiconductor layer includes: a first portion having a first width; and a second portion disposed closer to the active layer than the first portion and having a second width larger than the first width.

According to various aspects of the present disclosure, the mask pattern may be disposed between the growth substrate and the nitride semiconductor structure, such that the contact area between the growth substrate and the nitride semiconductor structure may be reduced. Accordingly, there is an effect of reducing crack defects occurring between the growth substrate and the nitride semiconductor structure in the laser lift-off process.

Further, as the contact area between the growth substrate and the nitride semiconductor structure is reduced, the contact area of the nitride semiconductor structure which the laser contact during the laser lift-off process is reduced. Thus, a space margin between adjacent light-emitting device chips may be reduced, thereby increasing the density of light-emitting device chips and improving a yield.

Further, as the passivation pattern that protects the outer surface of the nitride semiconductor structure is spaced away from the growth substrate, foreign material defects coming from the passivation pattern in the laser lift-off process may be reduced.

Further, as the passivation pattern is spaced away from the growth substrate, a sufficient thickness of the passivation pattern may be secured. Accordingly, the thickness of the passivation pattern may be sufficient to prevent damage that may occur on the side surface of the nitride semiconductor structure in the dry etching process, thereby compensating for a decrease in the external quantum efficiency (EQE).

In addition, the light-scattering pattern is disposed on the side surface of the lower portion of the first semiconductor layer of the nitride semiconductor structure to induce light-scattering. Thus, there is an effect of improving the light extraction efficiency and thus improving the performance of the light-emitting device chip. Accordingly, a relatively small current is required to drive the light-emitting device chip, thereby saving the power consumption.

In addition, the lower portion of the first semiconductor of the nitride semiconductor structure has the protruding shape. Thus, during bonding the light-emitting device to the package substrate, the light-emitting device may be fixedly inserted into the opening area (holder area). Thus, the plurality of light-emitting device chips may be easily respectively aligned with target positions on the package substrate and thus misalignment of the light-emitting devices may be prevented. Accordingly, a time required to align the plurality of light-emitting device chips with the target positions on the package substrate may be reduced, thereby simplifying the manufacturing process of the display apparatus.

Effects of the present disclosure are not limited to the effects mentioned above, and other effects not mentioned will be clearly understood by those skilled in the art from the description below.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a diagram showing a light-emitting device according to a first aspect of the present disclosure;

FIGS. 2A, 2B and 2C are diagrams showing a light-emitting device according to a second aspect of the present disclosure;

FIG. 3 is a diagram showing a light-emitting device according to a third aspect of the present disclosure;

FIG. 4 is a diagram showing a light-emitting device according to a fourth aspect of the present disclosure;

FIG. 5 is a diagram showing a display apparatus according to an aspect of the present disclosure;

FIG. 6 is a diagram showing a display apparatus according to another aspect of the present disclosure;

FIG. 7 is a diagram showing a display apparatus according to a further aspect aspect of the present disclosure; and

FIGS. 8-21 are diagram for illustrating a method for manufacturing a display apparatus in which a light-emitting device is disposed according to the present disclosure.

### DETAILED DESCRIPTION

Advantages and features of the present disclosure, and a method of achieving the advantages and features will become apparent with reference to aspects described later in detail together with the accompanying drawings. However, the present disclosure is not limited to the aspects as disclosed under, but may be implemented in various different forms. Thus, these aspects are set forth only to make the present disclosure complete, and to completely inform the scope of the present disclosure to those of ordinary skill in the technical field to which the present disclosure belongs.

A shape, a size, a ratio, an angle, a number, etc. disclosed in the drawings for describing the aspects of the present disclosure are exemplary, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular aspects only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various aspects of the present disclosure may be partially or entirely combined with each other, and may be technically associated with each other or operate with each other. The aspects may be implemented independently of each other and may be implemented together in an association relationship.

In interpreting a numerical value, the value is interpreted as including an error range unless there is separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various aspects of the present disclosure may be partially or entirely combined with each other, and may be technically associated with each other or operate with each other. The aspects may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display apparatus according to each aspect of the present disclosure will be described with reference to the accompanying drawings.

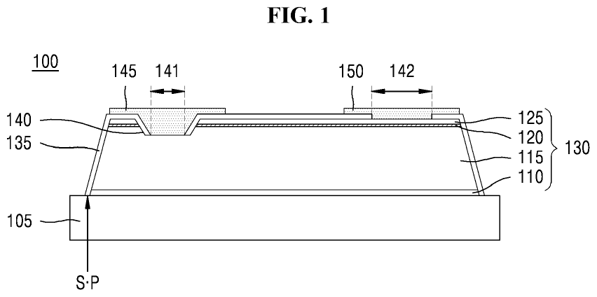

FIG. 1 is a diagram showing a light-emitting device according to a first aspect of the present disclosure.

Referring to FIG. 1, a light-emitting device 100 according to the first aspect may be disposed on a growth substrate 105. Although FIG. 1 shows only one light-emitting device 100 for convenience of illustration, a plurality of light-emitting devices may be arranged to be spaced apart from each other on the growth substrate 105. The light-emitting device 100 may include a nitride semiconductor structure 130, a passivation pattern 135 surrounding an outer surface of the nitride semiconductor structure 130, a first electrode 145, and a second electrode 150. The nitride semiconductor structure 130 may include a buffer semiconductor layer 110, a first semiconductor layer 115, an active layer 120, and a second semiconductor layer 125. In addition, the nitride semiconductor structure 130 may have a trench hole 140 defined therein which extends through the second semiconductor layer 125 and the active layer 120 and exposes a portion of the first semiconductor layer 115.

The passivation pattern 135 may cover the outer surface of the nitride semiconductor structure 130 and a side surface of the trench hole 140. The passivation pattern 135 serves to prevent damage that may occur on a side surface of the nitride semiconductor structure 130 during a dry etching process in forming the nitride semiconductor structure 130, thereby supplements characteristics of the device. The passivation pattern 135 is formed to have a very thin thickness. For example, the passivation pattern 135 may have a thickness of 100 nm to 120 nm, and may be formed to have a thickness not exceeding 120 nm.

Further, the passivation pattern 135 may include a first open area 141 exposing a portion of the surface of the first semiconductor layer 115 and a second open area 142 exposing a portion of a surface of the second semiconductor layer 125. The first electrode 145 contacts a portion of the first semiconductor layer 115 exposed through the first open area 141, and the second electrode 150 contacts a portion of the second semiconductor layer 125 exposed through the second open area 142. The first electrode 145 and the second electrode 150 may be insulated from each other via the passivation pattern 135.

In one example, the buffer semiconductor layer 110 as a bottommost portion of the nitride semiconductor structure 130 has a shape in which the entire bottom surface may be in contact with the growth substrate 105.

The individual light-emitting devices 100 respectively including the nitride semiconductor structures 130 may be removed from the growth substrate 105 to be separated from each other using a laser lift off process. However, crack defects may occur during the laser lift-off process. For example, the passivation pattern 135 may protect the nitride semiconductor structure 130 and improve the characteristics of a light-emitting device. In addition, as described above, the passivation pattern 135 is formed to have a thin thickness of 100 nm to 120 nm.

When the thickness of the passivation pattern 135 is too thick, for example, thicker than 120 nm, the thick passivation pattern 135 may be a starting point at which the cracks start during the laser lift-off process. A bottom surface S⋅P of the passivation pattern 135 is in contact with the growth substrate 105. When the crack occurs while the bottom surface S⋅P of the passivation pattern 135 is in contact with the growth substrate 105, a portion of the passivation pattern 135 removed from the nitride semiconductor structure 130) becomes a residue. The residue of the passivation pattern 135 removed from the nitride semiconductor structure 130 due to the cracks may act as a foreign matter in a subsequent process and may act as a cause of defects when the light-emitting device is transferred to a package substrate, thereby reducing reliability of the device.

To prevent such a defect, the passivation pattern 135 is formed to have a proper thickness such as 120 nm or less. However, as the thickness of the passivation pattern 135 becomes too thin, there is a limit to preventing the damage that may occur on the side surface of the nitride semiconductor structure 130 in a dry etching process. When the damage is not prevented but remains on the side surface of the nitride semiconductor structure 130, a large number of abnormal combinations of electrons and holes that do not participate in light emission occur on the outer surface of the nitride semiconductor structure 130. As a result, a light-emitting area may be significantly reduced. In this case, even when the same current is applied, the external quantum efficiency (EQE) decreases, the luminance is lowered and thus the light-emitting efficiency can be greatly reduced.

Accordingly, in an aspect of the present disclosure, a light-emitting device capable of preventing crack defects from occurring during the laser lift-off process to increase light-emitting efficiency, a display apparatus including the light-emitting device and a manufacturing method thereof will be described. This will be described with reference to the drawings below.

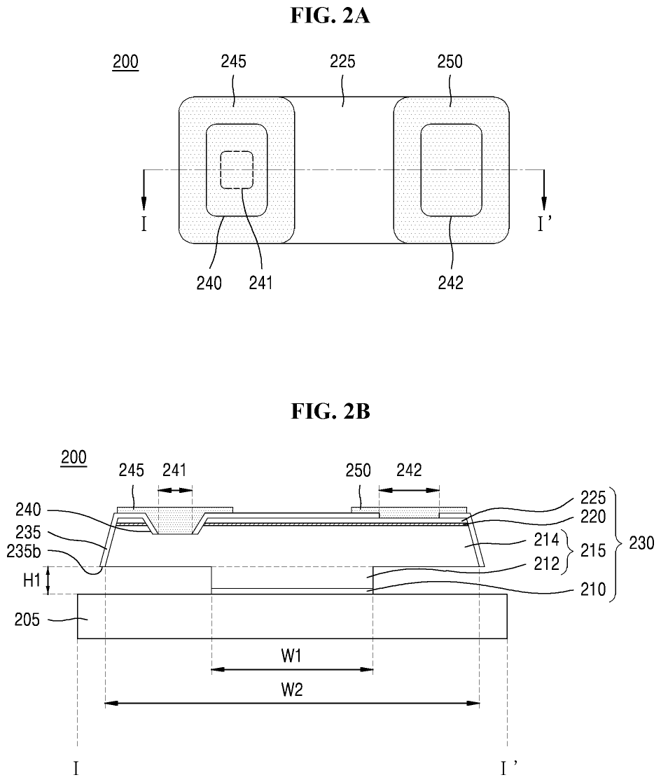

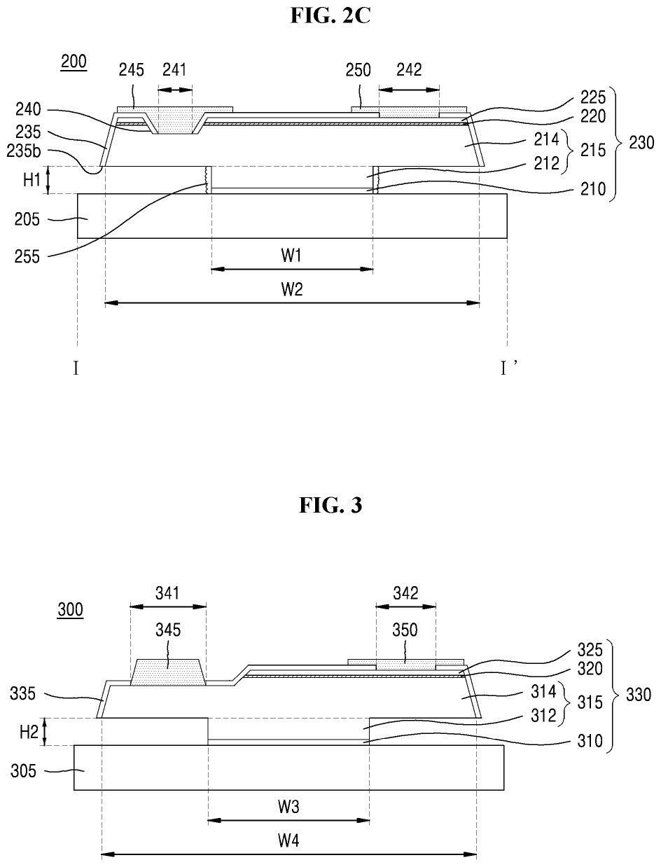

FIG. 2A to FIG. 2C are diagrams showing a light-emitting device according to a second aspect of the present disclosure. In this regard, FIG. 2A is a plan view of the light-emitting device, and FIG. 2B is a cross-sectional view cut along line I-I′ of FIG. 2A. FIG. 2C is a cross-sectional view showing a light-emitting device further including a light-scattering pattern in another example of the second aspect of the present disclosure.

Referring to FIGS. 2A to 2C, a light-emitting device 200 according to the second aspect of the present disclosure may include a nitride semiconductor structure 230, a passivation pattern 235, a first electrode 245, and a second electrode 250. The nitride semiconductor structure 230 may be disposed on a growth substrate 205. The light-emitting device 200 may refer to a device including components except for the growth substrate 205.

The nitride semiconductor structure 230 may include a buffer semiconductor layer 210, a first semiconductor layer 215, an active layer 220, and a second semiconductor layer 225. The first semiconductor layer 215 of the nitride semiconductor structure 230 may include a lower portion 212 having a first width W1 and an upper portion 214 having a second width W2 larger than the first width W1. The first semiconductor layer 215 may include a protrusion. The protrusion of the first semiconductor layer 215 is formed by undercutting the lower portion 214. The buffer semiconductor layer 210 positioned under the first semiconductor layer 215 may have the same width as the first width W1 of the lower portion 212 of the first semiconductor layer 215. Further, each of the active layer 220 and the second semiconductor layer 225 located above the first semiconductor layer 215 may have a width smaller than the second width W2 of the upper portion 214 of the first semiconductor layer 215. Accordingly, the lower portion 212 of the first semiconductor layer 215 may refer to the protrusion which may include the same material as a material of the upper portion 214 of the first semiconductor layer 215 and may be an overhang portion (or protrusion) of the upper portion 214 that is integrated with the upper portion 214. The first semiconductor layer 215 of the light-emitting device 200 according to an aspect of the present disclosure may include the protrusion protruding from one surface thereof.

For example, as shown in FIG. 2B, the nitride semiconductor structure 230 may have a ‘T’ shape in a cross-sectional view.

The passivation pattern 235 may have a shape covering a portion of an outer side surface and a portion of an upper surface of the nitride semiconductor structure 230. For example, the passivation pattern 235 may have a shape surrounding an outer side surface of each of the second semiconductor layer 225, the active layer 220, and the upper portion 214 of the first semiconductor layer 215. Accordingly, the outer side surface of the lower portion 212 of the first semiconductor layer 215 may be exposed outside the light emitting device. The passivation pattern 235 may cover the side surface of the nitride semiconductor structure 230 and not cover the outer side surface of the protrusion of the first semiconductor layer 215 to be exposed. Further, the passivation pattern 235 may include a first open area 241 exposing a portion of a surface of the first semiconductor layer 215 and a second open area 242 exposing a portion of a surface of the second semiconductor layer 225.

The first electrode 245 may contact a portion of the first semiconductor layer 215 exposed through the first open area 241, and the second electrode 250 may contact a portion of the second semiconductor layer 225 exposed through the second open area 242. The first electrode 245 and the second electrode 250 may be insulated from each other via the passivation pattern 235.

The buffer semiconductor layer 210 as the lowermost part of the nitride semiconductor structure 230 has a shape in which the entirety of a bottom surface contacts the growth substrate 205. In this case, the buffer semiconductor layer 210 has the same width as that of the lower portion 212 of the first semiconductor layer 215, and thus the buffer semiconductor layer 210 contacts the growth substrate 205 by a size of the first width W1 smaller than the second width W2. Further, since a bottom surface 235b of the passivation pattern 235 is spaced apart from a surface of the growth substrate 205 by a height H1 of the lower portion 212 of the first semiconductor layer 215, the passivation pattern 235 is not in contact with the growth substrate 205. Accordingly, the cracks may be prevented from occurring from the passivation pattern 235 in the laser lift-off process. Further, as the passivation pattern 235 does not contact and is apart from the surface of the growth substrate 205, the passivation pattern 235 may have a thickness larger than that of the passivation pattern 135 in the structure in which the lower portion 212 of the first semiconductor layer 215 is absent. For example, the thickness of the passivation pattern 235 may be greater than 120 nm. Accordingly, the passivation pattern 235 may have a thickness sufficient to prevent the damage to the side surface of the nitride semiconductor structure 230. In this case, the height H1 of the lower portion 212 of the first semiconductor layer 215 is smaller than a height of the first semiconductor layer 215.

As the damage to the side surface of the nitride semiconductor structure 230 due to plasma is prevented by the passivation pattern 235 having a sufficient thickness, abnormal electron-hole combination may be suppressed, thereby improving the light-emitting efficiency of the light-emitting device 200.

In another example, as shown in FIG. 2C, a light-scattering pattern 255 may be further disposed on an outer side surface of the lower portion 212 of the first semiconductor layer 215. The light-scattering pattern 255 may have a bumpy and irregular (or non-flat) surface. The light-scattering pattern 255 formed on the outer side surface of the lower portion 212 of the first semiconductor layer 215 induces scattering of emitted light, thereby improving light extraction efficiency of the light-emitting device 200. For example, when there is no light-scattering pattern 255, a refractive index of GaN-based nitride constituting the nitride semiconductor structure 230 may be about 2.4. In this case, the total internal reflection occurs and thus a large number of light beams may be extinguished therein such that light extraction efficiency may be reduced.

In this regard, as in an aspect of the present disclosure, when the lower portion 212 of the first semiconductor layer 215 includes the light-scattering pattern 255 disposed on the outer side surface thereof, light-scattering may repeatedly occur on the irregular surface of the light-scattering pattern 255 such that an amount of light emitted to the outside may increase, and thus the total internal reflectance may decrease. As a result, the light extraction efficiency at which the light is emitted to the outside is increased, thereby improving the performance of the light-emitting device.

The nitride semiconductor structure 230 may have a trench hole 240 defined therein which extends through the second semiconductor layer 225 and the active layer 220 and exposes a portion of the first semiconductor layer 215.

FIG. 3 is a diagram showing a light-emitting device according to a third aspect of the present disclosure.

Referring to FIG. 3, a light-emitting device 300 may include a nitride semiconductor structure 330, a passivation pattern 335, a first electrode 345, and a second electrode 350. The nitride semiconductor structure 330 may be disposed on the growth substrate 305. Since the light-emitting device 300 according to the third aspect of the present disclosure is the same as the light-emitting device according to the second aspect of FIG. 2A to FIG. 2C except that the light-emitting device 300 has a mesa structure, differences therebetween will be described, and descriptions of the same components may be omitted.

The nitride semiconductor structure 330 may include a buffer semiconductor layer 310, a first semiconductor layer 315, an active layer 320, and a second semiconductor layer 325. The first semiconductor layer 315 of the nitride semiconductor structure 330 may include a lower portion 312 having a first width W3 and an upper portion 314 having a second width W4 larger than a first width W3. The active layer 320 and the second semiconductor layer 325 of the nitride semiconductor structure 330 are disposed on one side of a top surface of the first semiconductor layer 315. In the other side of the top face to opposite to the one side of the top face thereof, a portion of a top surface of an upper portion 314 of the first semiconductor layer 315 is exposed due to mesa etching. Due to the mesa etching, the top surface of the upper portion 314 of the first semiconductor layer has a step. The first semiconductor layer 315 includes a lower portion 312 and the upper portion 314.

The buffer semiconductor layer 310 as the lowermost portion of the nitride semiconductor structure 330 may have the same width as the first width W3 of the lower portion 312 of the first semiconductor layer 315. Each of the active layer 320 and the second semiconductor layer 325 located above the first semiconductor layer 315 has a larger width than the first width W3 of the lower portion 312 of the first semiconductor layer 315, and has a smaller width than the second width W4 of the upper portion 314 of the first semiconductor layer 315. Accordingly, the lower portion 312 of the first semiconductor layer 315 may act as a protrusion which includes the same material as a material of the upper portion 314 of the first semiconductor layer 315 and is integral therewith and protrudes from the upper portion 314.

The passivation pattern 335 may have a shape covering an exposed surface of the nitride semiconductor structure 330 except for an outer side surface of the lower portion 312 of the first semiconductor layer 315. For example, the passivation pattern 335 may have a shape surrounding an outer side surface of each of the second semiconductor layer 325, the active layer 320, and the upper portion 314 of the first semiconductor layer 315. Accordingly, the outer side surface of the lower portion 312 of the first semiconductor layer 315 may be exposed to the outside. Further, the passivation pattern 335 may include a first open area 341 exposing a portion of the top surface of the first semiconductor layer 315 as exposed due to the mesa etching and a second open area 342 exposing a portion of a top surface of the second semiconductor layer 325.

The first electrode 345 may contact a portion of the first semiconductor layer 315 exposed through the first open area 341, while the second electrode 350 may contact a portion of the second semiconductor layer 325 exposed through the second open area 342. The first electrode 345 and the second electrode 350 may be insulated from each other via the passivation pattern 335.

Since the buffer semiconductor layer 310 as the lowermost part of the nitride semiconductor structure 330 has the same width as that of the lower portion 312 of the first semiconductor layer 315, the buffer semiconductor layer 310 contacts the growth substrate 305 by a size equal to the first width W3. Further, since a bottom surface of the passivation pattern 335 is spaced apart from a top surface of the growth substrate 305 by a height H2 of the lower portion 312 of the first semiconductor layer 315, the bottom surface of the passivation pattern 335 does not come into contact with the growth substrate 305. Thus, the cracks may be prevented from occurring from the passivation pattern 335 during the laser lift-off process. Further, the passivation pattern 335 has a thickness sufficient to prevent damage to the side surface of the nitride semiconductor structure 330. This may suppress abnormal electron-hole combination, thereby increasing light-emitting efficiency. In this case, the height H2 of the lower portion 312 of the first semiconductor layer 315 is smaller than a height of the first semiconductor layer 315.

Further, the light-scattering pattern 255 may be further disposed on the outer side surface of the lower portion 312 of the first semiconductor layer 315 (shown in FIG. 2C). The light-scattering pattern 255 may have a bumpy and irregular (or non-flat) surface. The light-scattering pattern 255 having the irregular surface may induce scattering of the emitted light to improve light extraction efficiency of the light-emitting device 300.

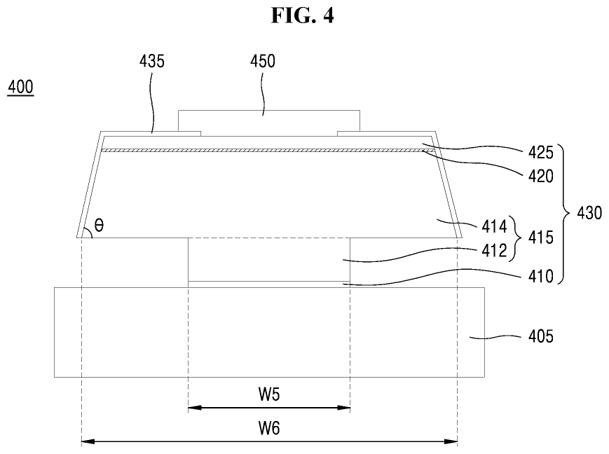

FIG. 4 is a diagram showing a light-emitting device according to a fourth aspect of the present disclosure.

Referring to FIG. 4, a light-emitting device 400 may include a nitride semiconductor structure 430, a passivation pattern 435, and a pad 450. The nitride semiconductor structure 430 may be disposed on a growth substrate 405. As the light-emitting device 400 according to the fourth aspect of the present disclosure is different from the light-emitting device according to the second aspect of FIG. 2A to FIG. 2C in that the light-emitting device 400 has a vertical structure, differences therebetween will be described.

The nitride semiconductor structure 430 may include a buffer semiconductor layer 410, a first semiconductor layer 415, an active layer 420, and a second semiconductor layer 425. The first semiconductor layer 415 of the nitride semiconductor structure 430 may include a lower portion 412 having a first width W5 and an upper portion 414 having a second width W6 larger than the first width W5. In the nitride semiconductor structure 430, the upper portion 414 of the first semiconductor layer 415, the active layer 420, and the second semiconductor layer 425 may be sequentially disposed on the lower portion 412. In the nitride semiconductor structure 430), an outer side surface of each of the active layer 420 and the second semiconductor layer 425 may be aligned with an outer side surface of the upper portion 414 of the first semiconductor layer 415 along an inclined line. For example, a width of the nitride semiconductor structure 430 may gradually decrease as the nitride semiconductor structure 430 extends from the upper portion 414 of the first semiconductor layer 415 toward the second semiconductor layer 425. In this case, an outer side surface of the nitride semiconductor structure 430 may be an inclined side surface. For example, the upper portion 414 of the first semiconductor layer 415 may have an inclined side surface having a predetermined inclination θ with respect to the bottom surface thereof. The nitride semiconductor structure 430 may have a ‘T’ shape in a cross-sectional view.

The buffer semiconductor layer 410 as the lowermost portion of the nitride semiconductor structure 430 may have the same width as the width W5 of the lower portion 412 of the first semiconductor layer 415. Each of the active layer 420 and the second semiconductor layer 425 located above the first semiconductor layer 415 may have a larger width than the first width W5 of the lower portion 412 of the first semiconductor layer 415.

The passivation pattern 435 may have a shape covering an exposed surface of the nitride semiconductor structure 430 except for an outer side surface of the lower portion 412 of the first semiconductor layer 415. For example, the passivation pattern 435 may have a shape surrounding an outer side surface of each of the second semiconductor layer 425, the active layer 420, and the upper portion 414 of the first semiconductor layer 415. Accordingly, the outer side surface of the lower portion 412 of the first semiconductor layer 415 may be exposed. Further, the passivation pattern 435 may include an open area exposing a portion of a top surface of the second semiconductor layer 425. The pad 450 may be disposed to be in contact with the portion of the top surface of the second semiconductor layer 425 exposed through the open area.

Since the buffer semiconductor layer 410 as the lowermost portion of the nitride semiconductor structure 430 has the same width as that of the lower portion 412 of the first semiconductor layer 415, the buffer semiconductor layer 410 contacts the growth substrate 405 by a size equal to the first width W5. Further, a bottom surface of the passivation pattern 435 is spaced apart from a top surface of the growth substrate 405 by a height of the lower portion 412 of the first semiconductor layer 415 and thus does not come into contact with the growth substrate 405. This may prevent cracks from occurring from the passivation pattern 435 during the laser lift-off process. Further, the passivation pattern 435 has a thickness sufficient to protect the side surface of the nitride semiconductor structure 430 from the damage that may occur during the dry etching process. Accordingly, abnormal electron-hole combination may be suppressed, and thus light-emitting efficiency of the light-emitting device 400 may be increased. In another example, the light-scattering pattern 255 (shown in FIG. 2C) may be further disposed on the outer side surface of the lower portion 412 of the first semiconductor layer 415.

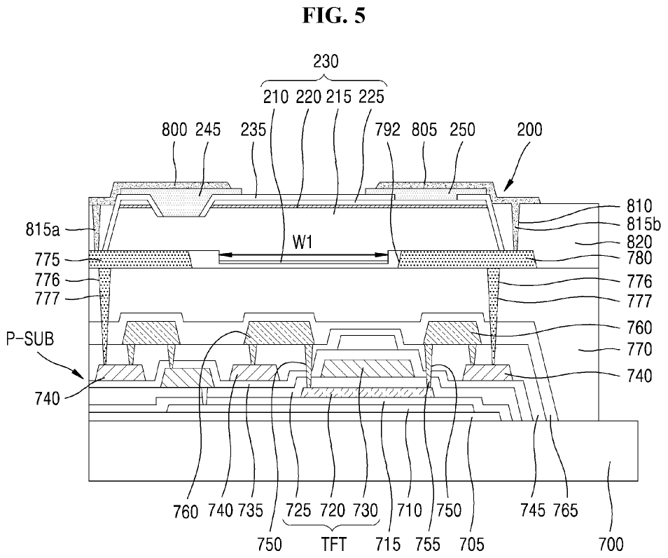

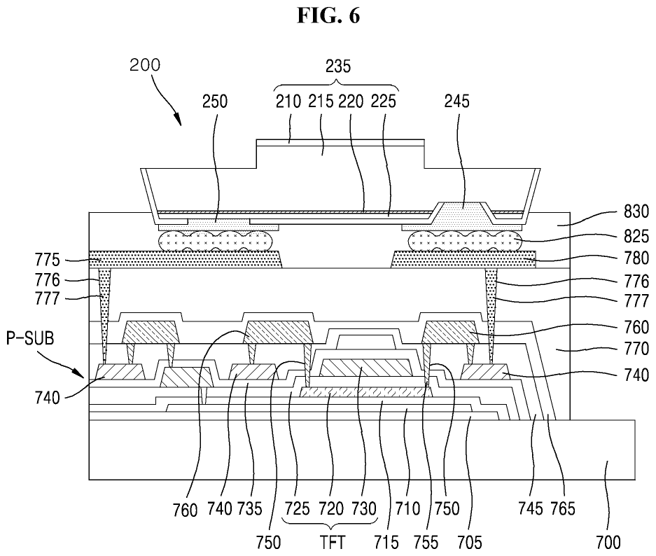

FIG. 5 is a diagram showing a display apparatus according to an aspect of the present disclosure.

Referring to FIG. 5, the display apparatus according to an aspect of the present disclosure includes a configuration in which a light-emitting device is bonded onto a package substrate P-SUB. For example, the light-emitting device may be embodied as the light-emitting device 200 of the second aspect of the present disclosure.

As described above, the light-emitting device 200 may include the nitride semiconductor structure 230, the passivation pattern 235, the first electrode 245, and the second electrode 250. Further, the nitride semiconductor structure 230 may include a buffer semiconductor layer 210, a first semiconductor layer 215, an active layer 220, and a second semiconductor layer 225 and may have a ‘T’ shape in a cross-sectional view. For example, the nitride semiconductor structure 230 may have a shape in which the lower portion of the first semiconductor layer 215 having the first width W1 downwardly protrudes from the upper portion thereof.

A plurality of circuit elements for driving the light-emitting devices are disposed in the package substrate P-SUB including a base substrate 700. Specifically, a thin-film transistor TFT is disposed in the package substrate P-SUB. The thin-film transistor TFT may include a semiconductor layer 720 formed on the base substrate 700, a gate electrode 730 located on the semiconductor layer 720, a gate insulating layer 725 between the semiconductor layer 720 and the gate electrode 730, and source and drain electrodes 760. A buffer layer 705 and a light-blocking film 710 may be disposed between the base substrate 700 and the semiconductor layer 720.

The buffer layer 705 may prevent diffusion of impurities or moisture from the base substrate 700 to the thin-film transistor TFT. The light-blocking layer 710 serves to prevent light from entering the semiconductor layer 720. A first interlayer insulating layer 715 may be disposed between the buffer layer 705, the light-blocking layer 710, and the semiconductor layer 720.

The gate electrode 730 may be disposed on the gate insulating layer 725 to overlap with the semiconductor layer 720. A second interlayer insulating layer 735 and a third interlayer insulating layer 745 may be sequentially disposed on the gate electrode 730.

A plurality of connection lines 740 may be disposed on the second interlayer insulating layer 735. The third interlayer insulating layer 745 may be positioned on the second interlayer insulating layer 735 and may cover the plurality of connection lines 740. The source and drain electrodes 760 may be disposed on the third interlayer insulating layer 745 while the gate electrode 730 is interposed between the source and drain electrodes 760. Source and drain contact-holes 750 may extend through the third interlayer insulating layer 745, the second interlayer insulating layer 735, and the gate insulating layer 725 to expose portions of source and drain areas of the semiconductor layer 720, respectively. The source and drain contact-holes 750 may be filled with the conductive material or a metal material to form source and drain contacts 755, respectively. Each of the source and drain electrodes 760 may be electrically connected to the semiconductor layer 720 and at least one connection line 740 via each of the source and drain contacts 755. In this case, one side of each of the source and drain electrodes 760 may be connected to the semiconductor layer 720, while the other side thereof may be connected to the connection line 740. The connection line 740 may include a voltage line such as a common voltage line.

A protective layer 765 is disposed on the third interlayer insulating layer 745. The protective layer 765 is formed to cover the source and drain electrodes 760. A planarization film 770 is disposed on the protective layer 765. The planarization film 770 may be thick enough to planarize a stepped upper surface caused by the underlying circuit elements.

A first connection electrode 775 and a second connection electrode 780 are disposed on the planarization film 770. Each of the first connection electrode 775 and the second connection electrode 780 may be connected to the connection line 740 disposed on the second interlayer insulating layer 735 via a conductive contact 777. To this end, a contact-hole 776 may extend through the planarization film 770, the protective layer 765, and the third interlayer insulating layer 745 and may be filled with a conductive material or a metal material to form the conductive contact 777. The conductive contact 777 may contact and be electrically connected to a bottom surface of each of the first connection electrode 775 and the second connection electrode 780.

A holder area 792 defining a position where the light-emitting device 200 is to be seated may be located between the first connection electrode 775 and the second connection electrode 780. In this regard, the first connection electrode 775 may be electrically connected to the connection line 740. Further, the second connection electrode 780 may be electrically connected to the thin-film transistor TFT.

In this regard, the light-emitting device 200 includes the lower portion 212 of the first semiconductor chip 215 protruding from the upper portion thereof (shown in FIG. 2A to FIG. 2C). Further, the protruding lower portion 212 of the first semiconductor chip 215 may be aligned such that the protruding lower portion 212 is inserted into the holder area 792 in which the light-emitting device 200 is to be seated. The package substrate P-SUB may include the holder area 792. The lower portion 212 of the first semiconductor chip 215 as the protrusion may be received in the holder area 792. Accordingly, when transferring the plurality of light-emitting devices 200 onto the package substrate P-SUB, there is an effect of easily aligning the light-emitting devices with target areas onto the package substrate P-SUB.

A cover film 820 is disposed on the light-emitting device 200 and the planarization film 770. The cover film 820 may be disposed to surround an outer side surface of the light-emitting device 200. For example, the cover film 820 may be made of a resin. A first line electrode 800 and a second line electrode 805 may be disposed on the cover film 820. The first line electrode 800 and the second line electrode 805 may respectively electrically connect the first electrode 245 connected to the first semiconductor layer 215 of the light-emitting device 200 and the second electrode 250 connected to the second semiconductor layer 225 to the circuit elements disposed in the package substrate P-SUB. The first electrode 245 and the second electrode 250 may be electrically connected to the circuit elements disposed in the package substrate P-SUB respectively via pad contacts 815a and 815b extending through the cover film 820 to be connected to the first line electrode 800 and the second line electrode 805, respectively. In this regard, the first line electrode 800 may be electrically connected to the first connection electrode 775 via the first pad contact 815a, while the second line electrode 805 may be electrically connected to the second connection electrode 780 via the second pad contact 815b filled in a through hole 810.

Each of the first line electrode 800 and the second line electrode 805 may be made of a metal material such as Au, W, Pt, Si, Ir, Ag, Cu, Ni, Ti, and Cr, or an alloy of at least two thereof. Further, each of the first line electrode 800 and the second line electrode 805 may include a transparent metal oxide such as Indium-Tin-Oxide (ITO) and Indium-Zinc-Oxide (IZO). The present disclosure is not limited thereto.

In another example, the light-emitting device may be mounted onto the package substrate in a flip-chip scheme. This will be described with reference to the drawings below.

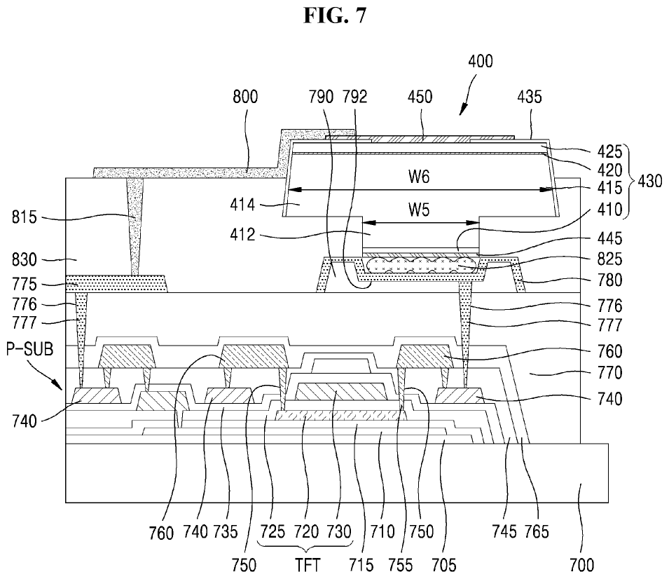

FIG. 6 is a diagram showing a display apparatus according to another aspect of the present disclosure. As each of the light-emitting device and the package substrate as shown in FIG. 6 includes the same components as those in FIG. 5, differences therebetween will be described below.

Referring to FIG. 6, a display apparatus according to another aspect of the present disclosure includes a configuration in which the light-emitting device is bonded onto the package substrate P-SUB. The light-emitting device may be embodied as the light-emitting device 200 of the second aspect of the present disclosure. In this case, the light-emitting device 200 has a flip-chip shape in which the first electrode 245 and the second electrode 250 thereof face the first connection electrode 775 and the second connection electrode 780 of the package substrate P-SUB, respectively.

The light-emitting device 200 and the package substrate P-SUB may be bonded with each other via a conductive adhesive material 825 such as a conductive ball. When the conductive adhesive material 825 is embodied as the conductive ball, an adhesive resin layer 830 may be disposed between the light-emitting device 200 and the package substrate P-SUB to fix the conductive ball.

FIG. 7 is a diagram showing a display apparatus according to still another aspect of the present disclosure. In this regard, the light-emitting device 400 shown in FIG. 7 includes the same configuration as that of the light-emitting device according to the fourth aspect of the present disclosure.

Referring to FIG. 7, the display apparatus according to still another aspect of the present disclosure includes a configuration in which the light-emitting device 400 is bonded onto the package substrate P-SUB.

The light-emitting device 400 may include the nitride semiconductor structure 430, the passivation pattern 435, the first electrode 445, and the second electrode 450. The nitride semiconductor structure 430 may include the buffer semiconductor layer 410, the first semiconductor layer 415, the active layer 420, and the second semiconductor layer 425. The first semiconductor layer 415 of the nitride semiconductor structure 430 may include the lower portion 412 having the first width W5 (shown in FIG. 4), and the upper portion 414 having the second width W6 larger than the first width W5. In other words, the nitride semiconductor structure 430 may have a shape in which the lower portion 412 of the first semiconductor layer 415 having the first width W5 downwardly protrudes from the upper portion 414.

A plurality of circuit elements for driving light-emitting device chips are disposed in the package substrate P-SUB including a base substrate 700. Specifically, thin-film transistors TFT are disposed in the package substrate P-SUB. The thin-film transistor TFT may include the semiconductor layer 720 formed on the base substrate 700, the gate electrode 730 located on the semiconductor layer 720, the gate insulating layer 725 between the semiconductor layer 720 and the gate electrode 730, and the source and drain electrodes 760. The buffer layer 705 and the light-blocking film 710 may be disposed between the base substrate 700 and the semiconductor layer 720.

The buffer layer 705 may prevent diffusion of impurities or moisture from the base substrate 700 to the thin-film transistor TFT. The light-blocking layer 710 serves to prevent light from entering the semiconductor layer 720. The first interlayer insulating layer 715 may be disposed between the buffer layer 705, the light-blocking layer 710, and the semiconductor layer 720.

The gate electrode 730 may be disposed on the gate insulating layer 725 to overlap with the semiconductor layer 720. The second interlayer insulating layer 735 and the third interlayer insulating layer 745 may be sequentially disposed on the gate electrode 730.

The plurality of connection lines 740 may be disposed on the second interlayer insulating layer 735. The third interlayer insulating layer 745 may be positioned on the second interlayer insulating layer 735 and may cover the plurality of connection lines 740. The source and drain electrodes 760 may be disposed on the third interlayer insulating layer 745 while the gate electrode 730 is interposed between the source and drain electrodes 760. The source and drain contact-holes 750 may extend through the third interlayer insulating layer 745, the second interlayer insulating layer 735, and the gate insulating layer 725 to expose portions of source and drain areas of the semiconductor layer 720, respectively. The source and drain contact-holes 750 may be filled with a conductive material or a metal material to form the source and drain contacts 755, respectively. Each of the source and drain electrodes 760 may be electrically connected to the semiconductor layer 720 and at least one connection line 740 via each of the source and drain contacts 755. In this case, one side of each of the source and drain electrodes 760 may be connected to the semiconductor layer 720, while the other side thereof may be connected to the connection line 740. The connection line 740 may include a voltage line such as a common voltage line.

The protective layer 765 is disposed on the third interlayer insulating layer 745. The protective layer 765 is formed to cover the source and drain electrodes 760. The planarization film 770 is disposed on the protective layer 765. The planarization film 770 may be thick enough to planarize a stepped upper surface caused by the underlying circuit elements.

The first connection electrode 775 and the second connection electrode 780 are disposed on the planarization film 770. Each of the first connection electrode 775 and the second connection electrode 780 may be connected to the connection line 740 disposed on the second interlayer insulating layer 735 via the conductive contact 777. To this end, the contact-hole 776 may extend through the planarization film 770, the protective layer 765, and the third interlayer insulating layer 745 and may be filled with a conductive material or a metal material to form the conductive contact 777. The conductive contact 777 may contact and be electrically connected to a bottom surface of each of the first connection electrode 775 and the second connection electrode 780. In this regard, the first connection electrode 775 may be electrically connected to the connection line 740. Further, the second connection electrode 780 may be electrically connected to the thin-film transistor TFT.

An upper insulating layer 790 may be formed under the second connection electrode 780. A holder area 792 defining a position where the light-emitting device 400 is to be seated may be defined by the upper insulating layer 790 and may be disposed on the second connection electrode 780.

The light-emitting device 400 includes the protruding lower portion 412 of the first semiconductor chip 415 (shown in FIG. 4). In addition, the protruding lower portion 412 of the first semiconductor chip 415 may be inserted into the holder area 792 on which the light-emitting device 400 is to be seated. Accordingly, when transferring the plurality of light-emitting devices 400 onto the package substrate P-SUB, there is an effect of easily aligning the light-emitting devices with target areas onto the package substrate P-SUB.

The light-emitting device 400 and the package substrate P-SUB may be bonded to each other via the conductive adhesive material 825 such as a conductive ball. When the conductive adhesive material 825 is embodied as the conductive ball, the adhesive resin layer 830 may be disposed between the light-emitting device 200 and the package substrate P-SUB to fix the conductive ball.

In the light-emitting device 400 having the vertical structure, pads are positioned to be opposite to each other in a vertical direction. For example, the first electrode 445 contacts the buffer semiconductor layer 410 and the first semiconductor layer 415, while the second electrode 450 opposed to the first electrode 445 contacts the second semiconductor layer 425. The line electrode 800 may be partially disposed on the second electrode 450 and may be electrically connected to one of the connection lines 740 via one of the conductive contacts 777. The line electrode 800 may be electrically connected to the first connection electrode 775 via a pad contact 815. Further, the first electrode 445 may be electrically connected to the second connection electrode 780 via the conductive adhesive material 825. The second connection electrode 780 may be electrically connected to another connection line 740) via the conductive contact 777.

In this regard, the light-emitting device 400 includes the protruding lower portion 412 of the first semiconductor chip 415 (shown in FIG. 4). Further, the protruding lower portion 412 of the first semiconductor chip 415 may be aligned with and may be inserted into the holder area 792. Accordingly, even when the plurality of light-emitting devices 400 are transferred onto the package substrate P-SUB, there is an effect of easily aligning the light-emitting devices with target areas onto the package substrate P-SUB.

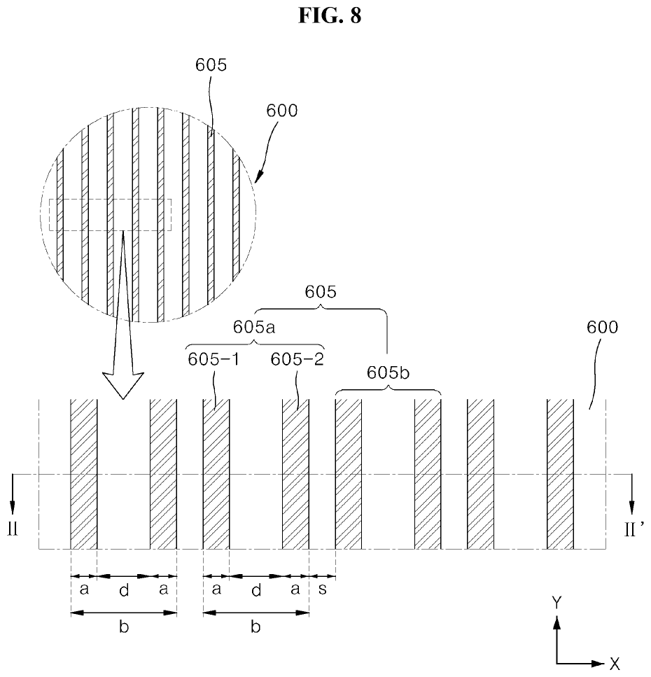

FIG. 8 to FIG. 21 are views for illustrating a method for manufacturing a display apparatus in which a light-emitting device according to an aspect of the present disclosure is disposed.

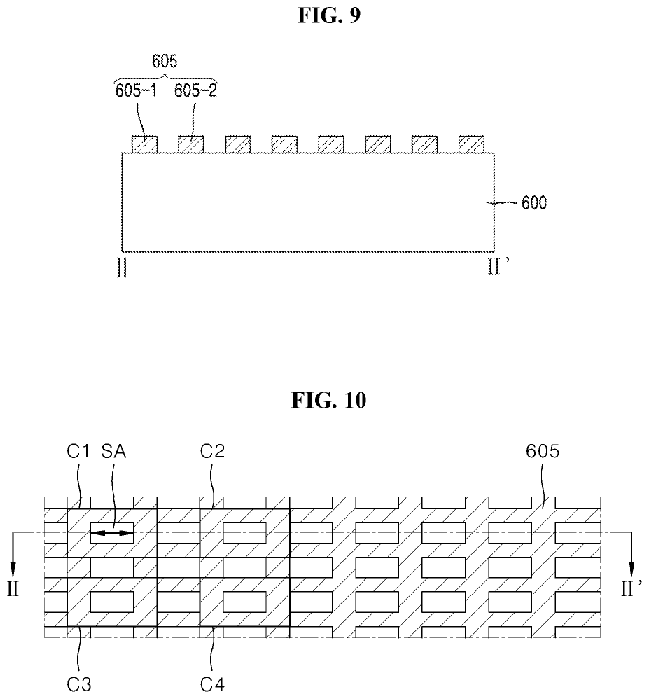

Initially referring to FIG. 8 to FIG. 10, a mask pattern 605 is formed on a growth substrate 600. To this end, a mask material layer is formed on the entire surface of the growth substrate 600, and a patterning process is performed to selectively remove the mask material layer to form a mask pattern 605. FIG. 9 is a cross-sectional view of FIG. 8 or FIG. 10 cut along line II-II′.

The growth substrate 600 may be made of a material such as sapphire, silicon (Si), silicon carbide (SiC) and gallium arsenide (GaAs). However, the present disclosure is not limited thereto. The mask material layer may include a material on which nitride-based semiconductor does not grow. Further, the mask material layer may include a material that may be easily removed using a wet etching solution. For example, the mask material layer is made of an insulating material including silicon oxide or indium-tin-oxide (ITO).

The mask pattern 605 includes a plurality of sub-patterns 605-1 and 605-2 which extend in a Y-axis direction as a first direction of the growth substrate 600, and are spaced apart from each other in an X-axis direction as a second direction that intersects the first direction. Thus, each of the plurality of sub-patterns 605-1 and 605-2 has a stripe shape.

For example, the first sub-pattern 605-1 and the second sub-pattern 605-2 disposed adjacent to the first sub-pattern 605-1 constituting one mask pattern 605a may have the same line width a. The second sub-pattern 605-2 may be spaced apart from the first sub-pattern 605-1 by a predetermined distance d. A size b as the sum of the line width a of the first sub-pattern 605-1, the line width a of the second sub-pattern 605-2, and the distance d between the first sub-pattern 605-1 and the second sub-pattern 605-2 may be a size of one light-emitting device to be formed later. In other words, an area in which one light-emitting device is disposed may correspond to one mask pattern 605a including the first sub-pattern 605-1 and the second sub-pattern 605-2.

Further, the first sub-patterns 605-1 and the second sub-patterns 605-2 may be repeatedly arranged in the X-axis direction as the second direction of the growth substrate 600. The mask pattern 605a corresponding to one light-emitting device and a mask pattern 605b corresponding to one light-emitting device and adjacent to the mask pattern 605a may be spaced apart from each other by a spacing s. In the drawings below, the mask pattern will be collective referred to as 605.

Referring to FIG. 10, the mask pattern 605 may be formed to include a plurality of lattice shapes, each lattice having a space SA defined therein. According to an aspect of the present disclosure, one lattice-shaped mask pattern 605 may have a width and a length of several to several tens of micrometers (μm). An area where each of light-emitting devices C1, C2, C3, and C4 is to be placed may be defined to include the space SA defined in the lattice shape.

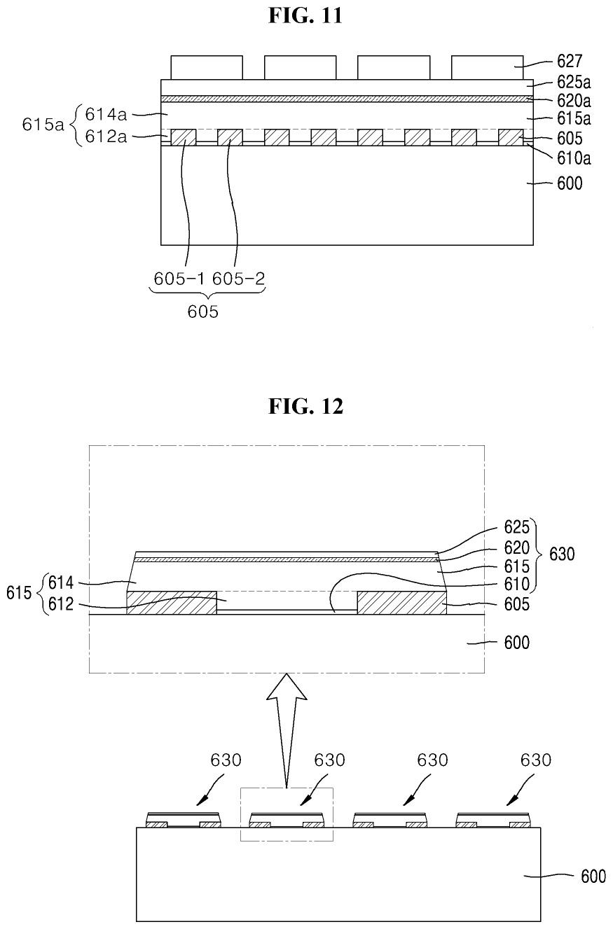

Referring to FIG. 11, an epitaxy process is performed on the growth substrate 600 on which the mask pattern 605 has been formed. The epitaxy process may be understood as a process of growing a material in a specific orientation relationship on a surface of a certain crystal. To form the nitride semiconductor structure of the micro-LED based light-emitting device, a GaN-based compound semiconductor should be deposited on the top surface of the growth substrate 600. At this time, each layer grows based on crystallinity of an underlying layer.

When the epitaxy process is performed, a buffer semiconductor material layer 610a, a first semiconductor material layer 615a, an active material layer 620a and a second semiconductor material layer 625a may be sequentially grown in an area between the sub-patterns 605-1 and 605-2 of the mask pattern adjacent to each other and on the growth substrate 600. In this regard, an area where the mask pattern 605 is disposed includes a material on which a semiconductor layer does not grow during the epitaxy process, and thus the buffer semiconductor material layer 610a, the first semiconductor material layer 615a, the active material layer 620a and the second semiconductor material layer 625a may be selectively grown only in the remaining area except for the mask pattern 605.

The buffer semiconductor material layer 610a as the lowermost layer may be formed to include undoped nitride semiconductor. For example, the nitride semiconductor may be a GaN-based semiconductor material. The first semiconductor material layer 615a is formed on a top surface of the buffer semiconductor material layer 610a. The first semiconductor material layer 615a may include a nitride semiconductor containing first conductivity type impurities. For example, the first conductivity-type impurity may include an N-type impurity. The nitride semiconductor of the first semiconductor material layer 615a may be made of a GaN-based semiconductor material including GaN, AlGaN, InGaN, or AlInGaN. The N-type impurity used for doping of the first semiconductor material layer 615a may include silicon (Si), germanium (Ge), selenium (Se), tellurium (Te), or carbon (C). The present disclosure is not limited thereto.

The first semiconductor material layer 615a grows to fill a space between the sub-mask patterns, and then has filled an entirety of the space and then may grow upwardly to a vertical level to have a predetermined thickness. For example, the first semiconductor material layer 615a may include a lower portion 612a filling the space between the sub-mask patterns 605. For example, the first semiconductor material layer 615 may include the lower portion 612a, and an upper portion 614a formed on the lower portion and the mask pattern 605.

The active material layer 620a is located on the top surface of the first semiconductor material layer 615a. The active material layer 620a may be a layer for emitting light based on combination of electrons and holes. The active material layer 620a includes a multi-quantum well (MQW) structure having a well layer and a barrier layer having a higher band gap than that of the well layer. For example, the active material layer 620a may include an InGaN layer as the well layer and an AlGaN layer as the barrier layer. However, the materials thereof are not limited thereto.

The second semiconductor material layer 625a is formed on the active material layer 620a. The second semiconductor material layer 625a may include a nitride semiconductor containing second conductivity type impurities. For example, the second conductivity type impurity may include a P-type impurity. The nitride semiconductor of the second semiconductor material layer 625a may be made of a GaN-based semiconductor material including GaN, AlGaN, InGaN, or AlInGaN. The P-type impurity contained in the second semiconductor material layer 625a may include manganese (Mg), zinc (Zn), or beryllium (Be).

In an aspect of the present disclosure, an example in which the first semiconductor material layer 615a and the second semiconductor material layer 625a include the nitride semiconductor containing N-type impurities and the nitride semiconductor containing P-type impurities, respectively, is described. However, the present disclosure is not limited thereto. In another example, the first semiconductor material layer 615a and the second semiconductor material layer 625a may include a nitride semiconductor including P-type impurities and a nitride semiconductor including N-type impurities, respectively.

Subsequently, an etch mask 627 protecting the underlying layers in a subsequent patterning process is formed on the second semiconductor material layer 625a. The etch mask 627 may be formed to have an opening defined therein exposing a portion of a surface of the second semiconductor material layer 625a other than a portion thereof where the nitride semiconductor structure is to be formed.

Referring to FIG. 12, the second semiconductor material layer 625a, the active material layer 620a, the first semiconductor material layer 615a, and the buffer semiconductor layer 610a may be patterned using the etch mask 627 (see FIG. 11) such that a plurality of nitride semiconductor structures 630 are formed on the growth substrate 600 to be spaced apart from each other. The patterning process may proceed in a dry etching scheme. The dry etching scheme may be carried out using an inductively coupled plasma-reactive ion etch (ICP-RIE) using a reactive gas. The portion exposed through the opening of the etching mask 627 may be sequentially etched by the patterning process. The patterning process may continue such that the surface of the growth substrate 600 is exposed. Then, adjacent nitride semiconductor structures 630 may be separated from each other.

Each of the nitride semiconductor structures 630 formed by the patterning process may include the buffer semiconductor layer 610, the first semiconductor layer 615, the active layer 620, and the second semiconductor layer 625. In this regard, the first semiconductor layer 615 may include the lower portion 612 located between the sub-mask patterns 605 and having the first width, and the upper portion 614 extending from the lower portion 612 toward the upper surface of the mask pattern 605 and having the second width larger than the first width of the lower portion 612. Accordingly, the nitride semiconductor structure 630) may have a ‘T’ shape in a cross-sectional view. Then, the etch mask 627 is removed.

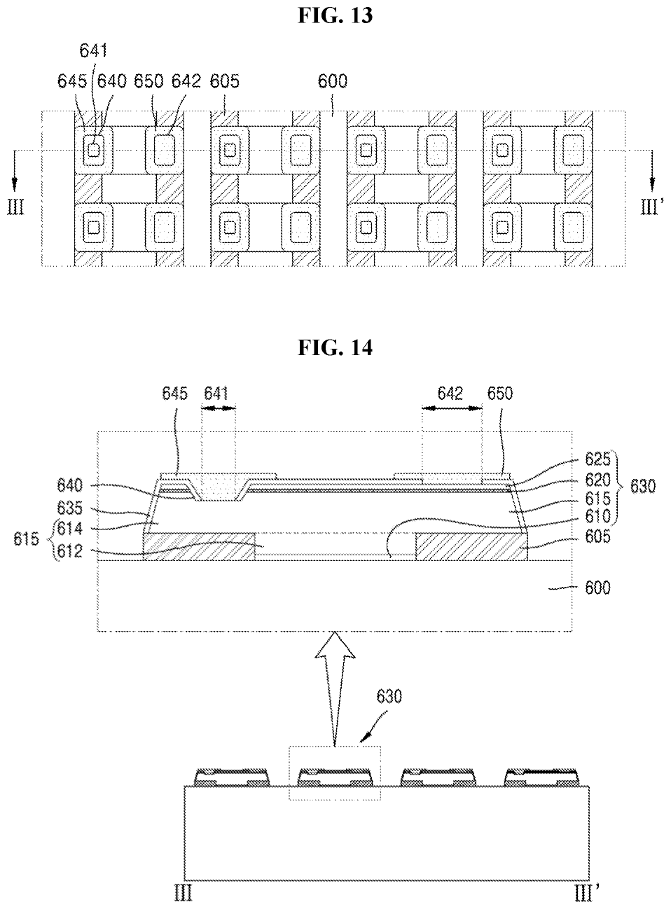

Referring to FIG. 13 and FIG. 14, a trench hole 640 is formed in the nitride semiconductor structure 630. In this regard, FIG. 13 is the top view showing FIG. 14. FIG. 14 is a cross-sectional view taken along line III-III′ of FIG. 13. The trench hole 640 may be formed using an etching process. The trench hole 640 may extend through the second semiconductor layer 625 and the active layer 620 as the topmost portions of the nitride semiconductor structure 630 and may have a trench shape having a bottom surface and a sidewall and defined in the first semiconductor layer 615. The first semiconductor layer 615 may be exposed through the bottom surface of the trench hole 640).

Subsequently, a passivation pattern 635 covering the outer surface of the nitride semiconductor structure 630 including the trench hole 640 is formed. The passivation pattern 635 may include an insulating material. In one example, the passivation pattern 635 may include silicon oxide (SiOx). However, the present disclosure is not limited thereto, and a material having insulating properties may be applied as a material thereof.

As the passivation pattern 635 is formed to cover the sidewall of the trench hole 640 except for the bottom surface thereof, the bottom surface of the trench hole 640 may act as a first open area 641 exposing a surface of the first semiconductor layer 615. Further, the passivation pattern 635 may have a second open area 642 defined therein exposing a portion of a surface of the second semiconductor layer 625 at a position spaced apart from the first open area 641.

The passivation pattern 635 serves to improve the characteristics of the light-emitting device. For example, a side surface of the nitride semiconductor structure 630 may be damaged by plasma during a dry etching process to separate adjacent nitride semiconductor structures 630 from each other. The passivation pattern 635 serves to protect the side surface of the nitride semiconductor structure 630 from the damage. Further, the passivation pattern 635 serves to electrically insulate the first electrode and the second electrode to be formed later from each other.

The passivation pattern 635 is an essential component for protecting the nitride semiconductor structure 630 and improving the characteristics of the light-emitting device. However, as shown in FIG. 1, the passivation pattern 635 has a limitation in that the passivation pattern 635 should be formed to have a small thickness of 100 nm to 120 nm. When the passivation pattern 135 (shown in FIG. 1) is formed to have a thickness greater than 120 nm, the thick passivation pattern 635 acts as a starting point at which a crack starts during the laser lift-off process. Further, the residue of the passivation pattern 135 having the crack which is removed from the nitride semiconductor structure acts as a foreign material in a subsequent process, and thus may act as a cause of defects when transferring the light-emitting device to the package substrate.

However, in an aspect of the present disclosure, the mask pattern 605 is disposed between the growth substrate 600 and the buffer semiconductor layer 610, such that a contact area between the growth substrate 605 and the buffer semiconductor layer 610 may be reduced by a width of an area in which the mask pattern 605 is disposed. Further, as the mask pattern 605 is disposed between the passivation pattern 635 and the growth substrate 600, the passivation pattern 635 may not come into contact with the growth substrate 600. In other words, the bottom surface of the passivation pattern 635 is spaced away from the top surface of the growth substrate 600.

Accordingly, a portion of the passivation pattern 635 which the laser is applied to in the laser lift-off process may be removed, thereby preventing the cracks from starting from the passivation pattern 635. Accordingly, the passivation pattern 635 may have a thickness larger than that of the passivation pattern in a structure in which the lower portion 612 of the first semiconductor layer 615 is absent. For example, the thickness of the passivation pattern 635 may be greater than 120 nm. Accordingly, the passivation pattern 635 may have a thickness sufficient to prevent damage to the side surface of the nitride semiconductor structure 630, such that the characteristics of the light-emitting device may be improved. In this case, the height of the lower portion 612 of the first semiconductor layer 615 is smaller than the height of the upper portion 614 of the first semiconductor layer 615.

After the passivation pattern 635 has been formed, a first electrode 645 extending along and on a portion of an upper surface of the passivation pattern 635 while contacting the first open area 641 may be formed. Further, a second electrode 650 extending along and on another portion of the upper surface of the passivation pattern 635 while contacting the second open area 642 may be formed.

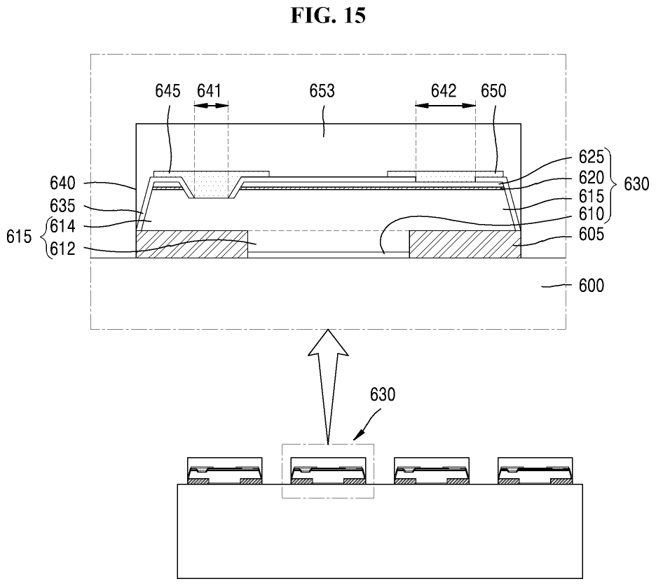

Referring to FIG. 15, an etch stop pattern 653 is formed on the nitride semiconductor structure 630. The etch stop pattern 653 may be formed to have a thickness sufficient to cover the passivation pattern 635 surrounding the outer surface of the nitride semiconductor structure 630. As shown in FIG. 15, the etch stop pattern 653 may be formed to have the same width as that of the nitride semiconductor structure 630. In one example, the etch stop pattern 653 may be formed by applying a photoresist material and performing exposure and development processes thereon.

As the etch stop pattern 653 is selectively formed only at a position where the nitride semiconductor structure 630 is disposed, the etch stop pattern 653 may include an opening area that selectively exposes the mask pattern 605 in the top view.

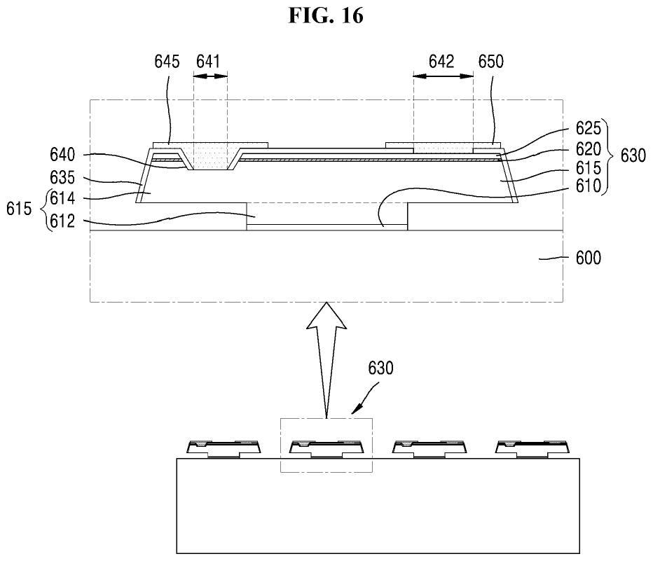

Referring to FIG. 16, the mask pattern 605 located under the nitride semiconductor structure 630 (shown in FIG. 15) is removed. The mask pattern 605 may be removed by performing a wet etching process on the growth substrate. The wet etching process may be performed using a buffered oxide etchant (BOE) solution in which hydrofluoric acid (HF) and ammonium fluoride (NH₄F) are mixed with each other or a wet etching solution containing hydrofluoric acid.

As the nitride semiconductor structure 630 is covered with the etch stop pattern 653, only the mask pattern 605 may be selectively removed while the nitride semiconductor structure 630 is affected by the wet etching solution. As the mask pattern 605 is selectively removed, an outer side surface of the lower portion 612 of the first semiconductor layer 615 may be exposed. Then, the etch stop pattern 653 is removed. In following drawings, the first semiconductor layer 615 including the lower portion 612 and the upper portion 614 will be shown as a single component in the drawing.

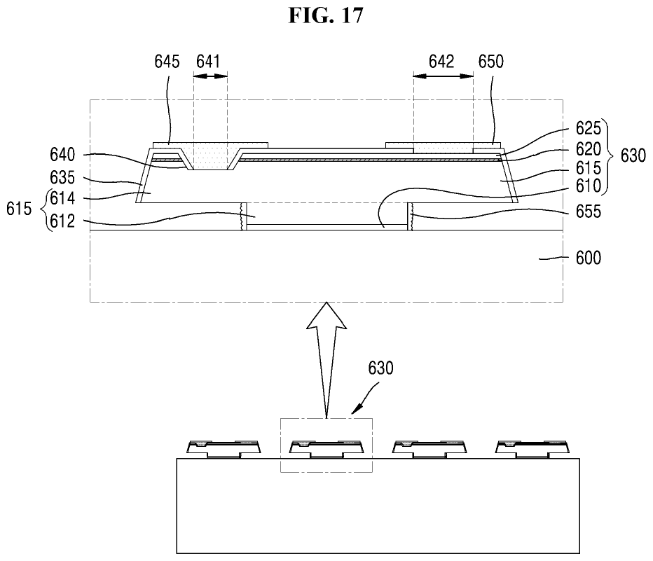

In another example, as shown in FIG. 17, the mask pattern may partially remain on the outer side surface of the lower portion 612 of the first semiconductor layer 615 and thus may act as the light-scattering pattern 655. The light-scattering pattern 655 may have a bumpy and irregular surface. The irregular surface of the light-scattering pattern 655 may be formed, for example, by adjusting a time for which the wet etching solution is applied in the wet etching process. For example, the wet etching solution supply time may be controlled such that the mask pattern is not entirely removed but partially remains on the outer side surface of the lower portion 612 of the first semiconductor layer 615. The light-scattering pattern 655 disposed on the side surface of the lower portion 612 of the first semiconductor layer 615 induces scattering of emitted light, thereby improving light extraction efficiency of the light-emitting device. For example, when there is no light-scattering pattern 255, the refractive index of GaN-based nitride constituting the nitride semiconductor structure may be 2.4. In this case, the refractive index has a high value, such that total internal reflection occurs and thus a large number of lights beams are extinguished therein, and thus the light extraction efficiency may be reduced.

In this regard, as in an aspect of the present disclosure, the light-scattering pattern 655 is disposed on the side surface of the lower portion 612 of the first semiconductor layer 615, such that light-scattering repeatedly occurs on the irregular surface of the light-scattering pattern 655. Thus, an amount of light emitted to the outside may increase and thus the total internal reflectance may decrease. As a result, the light extraction efficiency at which light is emitted to the outside may be increased, thereby improving the performance of the light-emitting device.

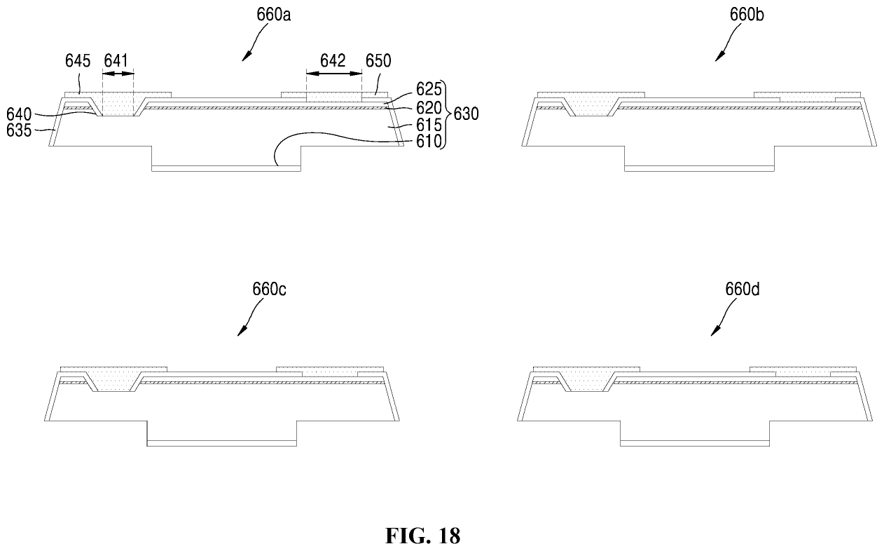

Referring to FIG. 18, the growth substrate 600 is removed from the nitride semiconductor structure 630 such that individual light-emitting devices 660a, 660b, 660c, and 660d are separated from each other. In this case, the growth substrate 600 may be removed using the laser in a laser lift off (LLO) process. When the individual light-emitting devices 660a. 660b, 660c, and 660d thus separated from each other are then transferred to the package substrate of the display apparatus, one light-emitting device may act as one pixel.

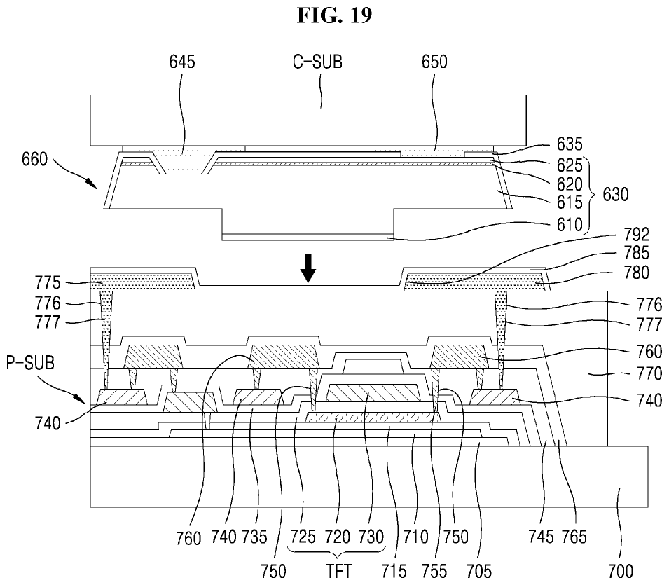

Referring to FIG. 19, the package substrate P-SUB is prepared and then the plurality of light-emitting devices 660 are transferred onto the package substrate P-SUB. The light-emitting device 660 may move to the package substrate while being attached to a carrier substrate C-SUB. The light-emitting device 660 may be aligned with the holder area 792 between the first connection electrode 775 and the second connection electrode 780 of the package substrate P-SUB.

A plurality of circuit elements for driving the light-emitting devices are disposed in the package substrate P-SUB including a base substrate 700. Specifically, thin-film transistors TFT are disposed in the package substrate P-SUB. The thin-film transistor TFT may include the semiconductor layer 720 formed on the base substrate 700, the gate electrode 730 located on the semiconductor layer 720, the gate insulating layer 725 between the semiconductor layer 720 and the gate electrode 730, and the source and drain electrodes 760. The buffer layer 705 and the light-blocking film 710 may be disposed between the base substrate 700 and the semiconductor layer 720.

The base substrate 700 may include any transparent material including glass or plastic. The buffer layer 705 may prevent diffusion of impurities or moisture from the base substrate 700 to the thin-film transistor TFT. The buffer layer 705 may include an inorganic insulating material. In one example, the buffer layer 705 may include silicon nitride or silicon oxide. The light-blocking layer 710 serves to prevent light from entering the semiconductor layer 720. The buffer layer 705 may be formed as a single layer or a stack of multiple layers. The light-blocking layer 710 serves to prevent light from being incident on the semiconductor layer 720 when the semiconductor layer 720 includes a metal oxide semiconductor. The first interlayer insulating layer 715 may be disposed between the buffer layer 705, the light-blocking layer 710, and the semiconductor layer 720.

The gate insulating layer 725 covering the semiconductor layer 720 may be disposed between the semiconductor layer 720 and the gate electrode 730. The gate insulating layer 725 may include at least one of an organic insulating material or an inorganic insulating material. The gate electrode 730 may be disposed on the gate insulating layer 725 to overlap with the semiconductor layer 720.

The second interlayer insulating layer 735 and the third interlayer insulating layer 745 may be sequentially disposed on the gate electrode 730. Each of the second interlayer insulating layer 735 and the third interlayer insulating layer 745 may include at least one of an organic insulating material or an inorganic insulating material.

The plurality of connection lines 740 may be disposed on the second interlayer insulating layer 735. The connection line 740 may include a voltage line such as a common voltage line. The third interlayer insulating layer 745 may be positioned on the second interlayer insulating layer 735 and may cover the plurality of connection lines 740. The source and drain electrodes 760 may be disposed on the third interlayer insulating layer 745 while the gate electrode 730 is interposed between the source and drain electrodes 760. The source and drain contact-holes 750 may extend through the third interlayer insulating layer 745, the second interlayer insulating layer 735, and the gate insulating layer 725 to expose portions of source and drain areas of the semiconductor layer 720, respectively. The source and drain contact-holes 750 may be filled with a conductive material or a metal material to form the source and drain contacts 755, respectively. Each of the source and drain electrodes 760 may be electrically connected to the semiconductor layer 720 and at least one connection line 740 via each of the source and drain contacts 755. In this case, one side of each of the source and drain electrodes 760 may be connected to the semiconductor layer 720, while the other side thereof may be connected to the connection line 740).

The protective layer 765 is disposed on the third interlayer insulating layer 745. The protective layer 765 is formed to cover the source and drain electrodes 760. The planarization film 770 is disposed on the protective layer 765. The planarization film 770 may be thick enough to planarize a stepped upper surface caused by the underlying circuit elements. The planarization film 770 may include an insulating material with excellent step coverage.

The first connection electrode 775 and the second connection electrode 780 are disposed on the planarization film 770. Each of the first connection electrode 775 and the second connection electrode 780 may be connected to the connection line 740 disposed on the second interlayer insulating layer 735 via the conductive contact 777. To this end, the contact-hole 776 may extend through the planarization film 770, the protective layer 765, and the third interlayer insulating layer 745 and may be filled with a conductive material or a metal material to form the conductive contact 777. The conductive contact 777 may contact and be electrically connected to a bottom surface of each of the first connection electrode 775 and the second connection electrode 780. The holder area 792 defining a position where the light-emitting device 660 is to be seated may be located between the first connection electrode 775 and the second connection electrode 780. In this regard, the first connection electrode 775 may be electrically connected to the connection line 740. Further, the second connection electrode 780 may be electrically connected to the thin-film transistor TFT.

An adhesive layer 785 is disposed on the planarization film 770, the first connection electrode 775 and the second connection electrode 780. The adhesive layer 785 may be formed to have a thickness sized such that the adhesive layer 785 covers all exposed surfaces of the first connection electrode 775, the second connection electrode 780, and the planarization film 770. The adhesive layer 785 serves to bond the light-emitting device 660 and the package substrate P-SUB to each other. The adhesive layer 785 has a viscosity before curing lower than a viscosity at which the adhesive layer 785 may fixedly bond the light-emitting device 660 and the package substrate P-SUB to each other. Thus, before curing, the light-emitting device 660 and the package substrate P-SUB may move relative to the adhesive layer 785 while not being fixed onto the adhesive layer 785. Subsequently, the light-emitting device 660 is displaced toward the package substrate P-SUB as indicated by an arrow in FIG. 19.

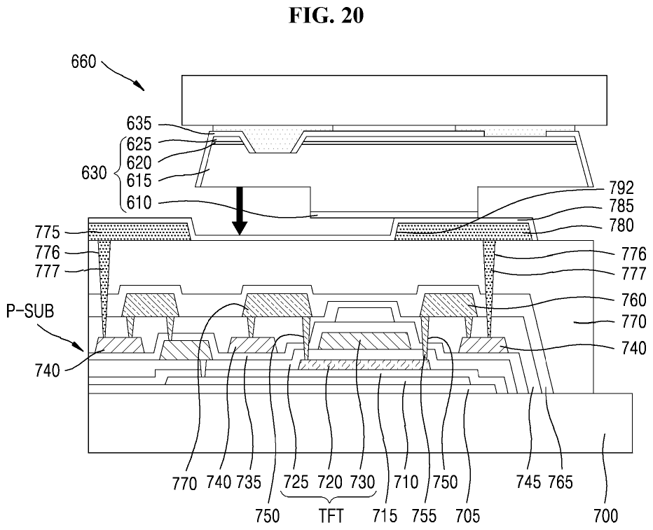

In one example, the light-emitting device 660 is positioned to be aligned with and be disposed on the holder area 792 defined between the first connection electrode 775 and the second connection electrode 780. As shown in FIG. 20, misalignment may occur during the transferring process. However, the light-emitting device 660 and the package substrate P-SUB may not be fixed to each other and may not be fixed onto the adhesive layer 785 and may move relative to each other before the curing of the adhesive layer. Thus, the light-emitting device 660 may be displaced to and aligned with the holder area 792.

In this regard, the first semiconductor layer 615 of the light-emitting device 660 includes the protruding lower portion. In addition, the protruding lower portion of the first semiconductor layer 615 may be aligned with and inserted into the holder area 792. Accordingly, there is an effect of easily aligning the plurality of light-emitting devices with the target areas of the package substrate, respectively in transferring the plurality of light-emitting devices onto a package substrate. Next, the light-emitting device 660 is fixed to the package substrate P-SUB by curing the adhesive layer 785.

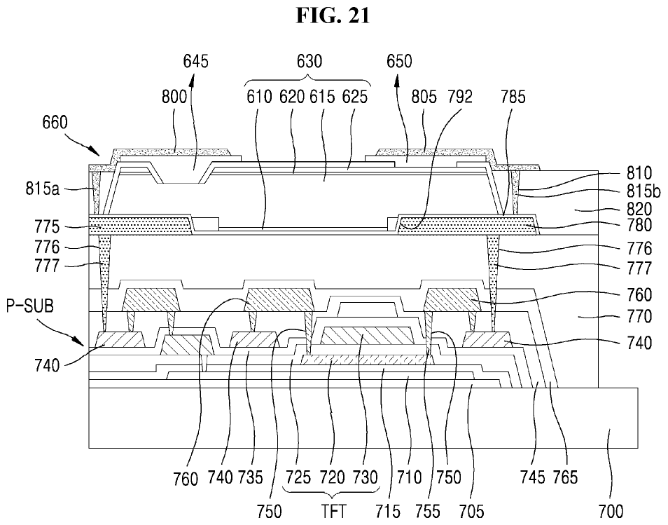

Referring to FIG. 21, the carrier substrate C-SUB is removed from the light-emitting device 660. Subsequently, the cover film 820 is formed on the light-emitting device 660 and the planarization film 770. The cover film 820 may be disposed to surround an outer side surface of the light-emitting device 660. For example, the cover film 820 may be made of a resin.

Next, the first line electrode 800 and the second line electrode 805 are formed on the cover film 820. The first line electrode 800 and the second line electrode 805 may respectively electrically connect the first electrode 645 connected to the first semiconductor layer 615 of the light-emitting device 660 and the second electrode 650 connected to the second semiconductor layer 625 thereof to the circuit elements disposed in the package substrate P-SUB. The first electrode 645 and the second electrode 650 may be electrically connected to the circuit elements disposed in the package substrate P-SUB respectively via pad contacts 815a and 815b extending through the cover film 820 to be connected to the first line electrode 800 and the second line electrode 805, respectively. In this regard, the first line electrode 800 may be electrically connected to the first connection electrode 775 via the first pad contact 815a, while the second line electrode 805 may be electrically connected to the second connection electrode 780 via the second pad contact 815b.

Each of the first line electrode 800 and the second line electrode 805 may be made of a metal material such as Au, W, Pt, Si, Ir, Ag, Cu, Ni, Ti, and Cr, or an alloy of at least two thereof. Further, each of the first line electrode 800 and the second line electrode 805 may include a transparent metal oxide such as indium-tin-oxide (ITO) and indium-zinc-oxide (IZO). Aspects of the present disclosure are not limited thereto.

According to the above aspects of the present disclosure, the mask pattern including a material on which the semiconductor layer cannot grow may be disposed on the growth substrate and then an epitaxy process for growing the nitride semiconductor layer may be carried out. Thus, the contact area between the growth substrate and the nitride semiconductor structure may be reduced. Accordingly, crack defects occurring between the growth substrate and the nitride semiconductor structure may be reduced during the laser lift-off process of removing the nitride semiconductor structure from the growth substrate.

Further, as the contact area between the growth substrate and the nitride semiconductor structure is reduced, the contact area of the nitride semiconductor structure which the laser contact during the laser lift-off process is reduced. Thus, a space margin between adjacent light-emitting device chips may be reduced, thereby increasing the density of light-emitting device chips and improving a yield.

Further, as the passivation pattern that protects the outer surface of the nitride semiconductor structure is spaced away from the growth substrate, foreign material defects coming from the passivation pattern in the laser lift-off process may be reduced.

Further, as the passivation pattern is spaced away from the growth substrate, a sufficient thickness of the passivation pattern may be secured. Accordingly, the thickness of the passivation pattern may be sufficient to prevent damage that may occur on the side surface of the nitride semiconductor structure in the dry etching process, thereby compensating for a decrease in the external quantum efficiency (EQE).

In addition, the light-scattering pattern is disposed on the side surface of the lower portion of the first semiconductor layer of the nitride semiconductor structure to induce light-scattering. Thus, there is an effect of improving the light extraction efficiency and thus improving the performance of the light-emitting device chip. Accordingly, a relatively small current is required to drive the light-emitting device chip, thereby saving the power consumption.

In addition, the lower portion of the first semiconductor of the nitride semiconductor structure has the protruding shape. Thus, during bonding the light-emitting device to the package substrate, the light-emitting device may be fixedly inserted into the opening area (holder area). Thus, the plurality of light-emitting device chips may be easily respectively aligned with target positions on the package substrate and thus misalignment of the light-emitting devices may be prevented. Accordingly, a time required to align the plurality of light-emitting device chips with the target positions on the package substrate may be reduced, thereby simplifying the manufacturing process of the display apparatus.

A display apparatus according to the aspect of the present disclosure may be described as follows.

A first aspect of the present disclosure provides a light-emitting device comprising: a nitride semiconductor structure including a first semiconductor layer, an active layer and a second semiconductor layer disposed sequentially; and a passivation pattern disposed on an outer surface of the nitride semiconductor structure, wherein the first semiconductor layer includes a protrusion, the protrusion protrudes in a direction away from the active layer.

In one implementation of the light-emitting device, the protrusion is made of the same material as a material of the first semiconductor layer and is integral with the first semiconductor layer.

In one implementation of the light-emitting device, the first semiconductor layer includes: a lower portion having a first width; and an upper portion disposed on the lower portion and having a second width larger than the first width, wherein the protrusion is the lower portion.

In one implementation of the light-emitting device, the passivation pattern exposes an outer side surface of the protrusion of the first semiconductor layer and covers the outer surface of the nitride semiconductor structure.

In one implementation of the light-emitting device, the light-emitting device further comprises a light-scattering pattern disposed on an outer side surface of the protrusion.

In one implementation of the light-emitting device, the nitride semiconductor structure has a T-shape in a cross-sectional view of the light-emitting device.

In one implementation of the light-emitting device, the active layer of the nitride semiconductor structure is disposed on one side of a top surface of the first semiconductor layer, wherein the second semiconductor layer is disposed on the active layer, wherein the other side of the top surface opposite to the one side of the top surface of the first semiconductor layer is exposed.

In one implementation of the light-emitting device, a side surface of each of the active layer and the second semiconductor layer of the nitride semiconductor structure are aligned with a side surface of the upper portion of the first semiconductor layer.

In one implementation of the light-emitting device, the passivation pattern includes a first open area exposing a portion of the first semiconductor layer and a second open area exposing a portion of the second semiconductor layer, and wherein the light-emitting device further includes a first electrode and a second electrode, the first electrode contacts the portion of the first semiconductor layer exposed through the first open area, and the second electrode contacts the portion of the second semiconductor layer exposed through the second open area.

A second aspect of the present disclosure provides a display apparatus comprising: a package substrate in which a plurality of circuit elements are disposed, wherein the package substrate includes a holder area; and a light-emitting device, wherein the light-emitting device includes: a nitride semiconductor structure including a first semiconductor layer, an active layer, and a second semiconductor layer disposed sequentially; and a passivation pattern disposed on an outer surface of the nitride semiconductor structure, wherein the first semiconductor layer includes a protrusion, the protrusion protrudes in a direction away from the active layer, wherein the protrusion is disposed in the holder area.

In one implementation of the display apparatus, the first semiconductor layer includes: a lower portion having a first width; and an upper portion disposed on the lower portion and having a second width larger than the first width, wherein the protrusion is the lower portion.

In one implementation of the display apparatus, the passivation pattern exposes an outer side surface of the protrusion of the first semiconductor layer and covers a side surface of the nitride semiconductor structure.

In one implementation of the display apparatus, the light-emitting device further includes a light-scattering pattern disposed on an outer side surface of the protrusion of the first semiconductor layer.

In one implementation of the display apparatus, the light-emitting device and the package substrate are bonded to each other via a conductive adhesive material.

In one implementation of the display apparatus, the conductive adhesive material is a conductive ball, an adhesive resin layer is disposed between the light-emitting device and the package substrate to fix the conductive ball.

In one implementation of the display apparatus, the active layer of the nitride semiconductor structure is disposed on one side of a top surface of the first semiconductor layer, wherein the second semiconductor layer is disposed on the active layer, wherein the other side of the top surface opposite to the one side of the top surface of the first semiconductor layer is exposed.

A third aspect of the present disclosure provides a display apparatus comprising: a package substrate in which a plurality of circuit elements are disposed; and a light-emitting device, wherein the light-emitting device includes: a nitride semiconductor structure including a first semiconductor layer, an active layer, and a second semiconductor layer disposed sequentially; and a passivation pattern disposed on an outer surface of the nitride semiconductor structure, wherein the light-emitting device and the package substrate are bonded to each other via a conductive adhesive material.

In one implementation of the display apparatus, the conductive adhesive material is a conductive ball, an adhesive resin layer is disposed between the light-emitting device and the package substrate to fix the conductive ball.

A fourth aspect of the present disclosure provides a method for manufacturing a display apparatus, the method comprising: providing a light-emitting device, wherein the light-emitting device includes a nitride semiconductor structure, and a passivation pattern disposed on an outer surface of the nitride semiconductor structure, wherein the nitride semiconductor structure includes a first semiconductor layer, an active layer and a second semiconductor layer disposed sequentially, wherein the first semiconductor layer includes a lower portion and an upper portion with a width larger than that of the lower portion; providing a package substrate having a holder area defined therein with which the light-emitting device are aligned, wherein a plurality of circuit elements for driving the light-emitting device is disposed in the package substrate; placing the lower portion of the first semiconductor layer into the holder area; and bonding the package substrate and the light-emitting device to each other. In one implementation of the method, providing the light-emitting device includes: forming a mask pattern on a growth substrate; sequentially forming a first semiconductor material layer, an active material layer, and a second semiconductor material layer on the mask pattern; forming an etch mask on the second semiconductor material layer; performing an etching process using the etching mask such that a surface of the growth substrate is exposed, thereby forming the nitride semiconductor structure; forming the passivation pattern to be disposed on the outer surface of the nitride semiconductor structure; forming an etch stop pattern covering the nitride semiconductor structure except for the mask pattern; removing the mask pattern to expose an outer side surface of the lower portion of the first semiconductor layer; and removing the growth substrate from the nitride semiconductor structure.

In one implementation of the method, the mask pattern includes an insulating material removable using a wet etching solution, wherein a nitride semiconductor cannot grow on the insulating material.

In one implementation of the method, the mask pattern includes a plurality of sub-patterns extending in a stripe shape in a first direction of the growth substrate and arranged to be spaced apart from each other in a second direction intersecting the first direction.

In one implementation of the method, the mask pattern is formed in a shape of a plurality of lattices, each lattice having a space defined therein.

In one implementation of the method, sequentially forming the first semiconductor material layer, the active material layer, and the second semiconductor material layer on the mask pattern includes: forming the lower portion of the first semiconductor material layer in an area between adjacent ones of a plurality of sub-mask patterns of the mask pattern; and forming the upper portion of the first semiconductor material layer on the mask pattern and on the lower portion of the first semiconductor material layer.

In one implementation of the method, providing the light-emitting device further includes forming a light-scattering pattern having an irregular surface on the exposed outer side surface of the lower portion of the first semiconductor layer, wherein forming the light-scattering pattern includes performing a wet etching process on the mask pattern such that the mask pattern remains on the exposed outer side surface of the lower portion.

A fifth aspect of the present disclosure provides a light-emitting device comprising: a first semiconductor layer, an active layer and a second semiconductor layer disposed sequentially; and a passivation pattern disposed on an outer surface of the first semiconductor layer, the active layer and the second semiconductor layer, wherein the first semiconductor layer includes: a first portion having a first width; and a second portion disposed closer to the active layer than the first portion and having a second width larger than the first width.

In one implementation of the light-emitting device, the first portion is made of the same material as a material of the second portion and is integral with the second portion.

In one implementation of the light-emitting device, the passivation pattern exposes an outer side surface of the first portion of the first semiconductor layer and covers the outer surfaces of the first semiconductor layer, the active layer and the second semiconductor layer,

In one implementation of the light-emitting device, further comprising a light-scattering pattern disposed on an outer side surface of the first portion.

In one implementation of the light-emitting device, the active layer of the nitride semiconductor structure is disposed on one side of a top surface of the first semiconductor layer, wherein the second semiconductor layer is disposed on the active layer, wherein the other side of the top surface opposite to the one side of the top surface of the first semiconductor layer is exposed.

In one implementation of the light-emitting device, a side surface of each of the active layer and the second semiconductor layer of the nitride semiconductor structure are aligned with a side surface of the second portion of the first semiconductor layer.

In one implementation of the light-emitting device, the passivation pattern includes a first open area exposing a portion of the first semiconductor layer and a second open area exposing a portion of the second semiconductor layer, and wherein the light-emitting device further includes a first electrode and a second electrode, the first electrode contacts the portion of the first semiconductor layer exposed through the first open area, and the second electrode contacts the portion of the second semiconductor layer exposed through the second open area.

It will be apparent to those skilled in the art that various modifications and variations can be made in the light-emitting device, the display apparatus including the same and the method for manufacturing the same of the present disclosure without departing from the spirit or scope of the aspects. Thus, it is intended that the present disclosure covers the modifications and variations of the aspects provided they come within the scope of the appended claims and their equivalents.

What is claimed is:

1. A light-emitting device comprising:
a nitride semiconductor structure including a first semiconductor layer, an active layer and a second semiconductor layer sequentially disposed on one another; and
a passivation pattern disposed on an outer surface of the nitride semiconductor structure,
wherein the first semiconductor layer includes a protrusion that protrudes in a direction away from the active layer.

2. The light-emitting device of claim 1, wherein the protrusion is made of a same material as the first semiconductor layer and is integrated with the first semiconductor layer.

3. The light-emitting device of claim 1, wherein the first semiconductor layer includes:
a lower portion having a first width; and
an upper portion disposed on the lower portion and having a second width larger than the first width,
wherein the lower portion is the protrusion that is integrated with the first semiconductor layer.

4. The light-emitting device of claim 1, wherein the passivation pattern exposes an outer side surface of the protrusion of the first semiconductor layer and covers the outer surface of the nitride semiconductor structure.

5. The light-emitting device of claim 1, further comprising a light-scattering pattern disposed on an outer side surface of the protrusion.

6. The light-emitting device of claim 1, wherein the nitride semiconductor structure has a T-shape in a cross-sectional view of the light-emitting device.

7. The light-emitting device of claim 1, wherein the active layer of the nitride semiconductor structure is disposed on one side of a top surface of the first semiconductor layer,
wherein the second semiconductor layer is disposed on the active layer, and
wherein another side of the top surface opposite to the one side of the top surface of the first semiconductor layer is exposed.

8. The light-emitting device of claim 3, wherein a side surface of each of the active layer and the second semiconductor layer of the nitride semiconductor structure are aligned with a side surface of the upper portion of the first semiconductor layer.

9. The light-emitting device of claim 1, wherein the passivation pattern includes a first open area exposing a portion of the first semiconductor layer and a second open area exposing a portion of the second semiconductor layer,
wherein the light-emitting device further comprises a first electrode and a second electrode, and
wherein the first electrode contacts the portion of the first semiconductor layer exposed through the first open area, and the second electrode contacts the portion of the second semiconductor layer exposed through the second open area.

10. A display apparatus comprising:
a plurality of circuit elements disposed on a package substrate having a holder area; and
a light-emitting device,
wherein the light-emitting device includes:
a nitride semiconductor structure including a first semiconductor layer, an active layer, and a second semiconductor layer sequentially disposed on one another; and
a passivation pattern disposed on an outer surface of the nitride semiconductor structure, wherein the first semiconductor layer includes a protrusion protruding in a direction away from the active layer and the protrusion is disposed in the holder area.

11. The display apparatus of claim 10, wherein the first semiconductor layer includes:
a lower portion having a first width; and
an upper portion disposed on the lower portion and having a second width larger than the first width,
wherein the lower portion is the protrusion.

12. The display apparatus of claim 10, wherein the passivation pattern exposes an outer side surface of the protrusion of the first semiconductor layer and covers a side surface of the nitride semiconductor structure.

13. The display apparatus of claim 10, wherein the light-emitting device further comprises a light-scattering pattern disposed on an outer side surface of the protrusion of the first semiconductor layer.

14. The display apparatus of claim 10, wherein the light-emitting device and the package substrate are bonded with each other via a conductive adhesive material.

15. The display apparatus of claim 14, wherein the conductive adhesive material includes:
a conductive ball;
an adhesive resin layer fixing the conductive ball and disposed between the light-emitting device and the package substrate.

16. The display apparatus of claim 10, wherein the active layer of the nitride semiconductor structure is disposed on one side of a top surface of the first semiconductor layer,
wherein the second semiconductor layer is disposed on the active layer,
wherein another side of the top surface opposite to the one side of the top surface of the first semiconductor layer is exposed.

17. A display apparatus comprising:
a plurality of circuit elements disposed on a package substrate; and
a light-emitting device,
wherein the light-emitting device includes:
a nitride semiconductor structure including a first semiconductor layer, an active layer, and a second semiconductor layer sequentially disposed on one another; and
a passivation pattern disposed on an outer surface of the nitride semiconductor structure,
wherein the light-emitting device and the package substrate are bonded with each other via a conductive adhesive material.

18. The display apparatus of claim 17, wherein the conductive adhesive material includes a conductive ball and an adhesive resin layer fixing the conductive ball, and the adhesive resin layer is disposed between the light-emitting device and the package substrate.

19. A method for manufacturing a display apparatus, the method comprising:
providing a light-emitting device including a nitride semiconductor structure, and a passivation pattern disposed on an outer surface of the nitride semiconductor structure, wherein the nitride semiconductor structure includes a first semiconductor layer, an active layer and a second semiconductor layer sequentially disposed on one another, and wherein the first semiconductor layer includes a lower portion and an upper portion with a width larger than that of the lower portion;
providing a package substrate having a holder area defined therein with which the light-emitting device are aligned, wherein a plurality of circuit elements for driving the light-emitting device is disposed in the package substrate;
placing the lower portion of the first semiconductor layer into the holder area; and
bonding the package substrate and the light-emitting device with each other.

20. The method of claim 19, wherein providing the light-emitting device includes:
forming a mask pattern on a growth substrate;
sequentially forming a first semiconductor material layer, an active material layer, and a second semiconductor material layer on the mask pattern;
forming an etch mask on the second semiconductor material layer;
performing an etching process using the etching mask to expose a surface of the growth substrate and form the nitride semiconductor structure;
forming the passivation pattern to be disposed on the outer surface of the nitride semiconductor structure;
forming an etch stop pattern covering the nitride semiconductor structure except for the mask pattern;
removing the mask pattern to expose an outer side surface of the lower portion of the first semiconductor layer; and
removing the growth substrate from the nitride semiconductor structure.

21. The method of claim 20, wherein the mask pattern includes an insulating material removable using a wet etching solution, and a nitride semiconductor cannot grow on the insulating material.

22. The method of claim 20, wherein the mask pattern includes a plurality of sub-patterns extending in a stripe shape in a first direction of the growth substrate and spaced apart from each other in a second direction intersecting the first direction.

23. The method of claim 20, wherein the mask pattern is formed in a shape of a plurality of lattices, each lattice having a space defined therein.

24. The method of claim 20, wherein sequentially forming the first semiconductor material layer, the active material layer, and the second semiconductor material layer on the mask pattern includes:
forming the lower portion of the first semiconductor material layer in an area between adjacent sub-mask patterns among a plurality of sub-mask patterns of the mask pattern; and
forming the upper portion of the first semiconductor material layer on the mask pattern and on the lower portion of the first semiconductor material layer.

25. The method of claim 20, wherein the providing the light-emitting device further includes forming a light-scattering pattern having an irregular surface on the exposed outer side surface of the lower portion of the first semiconductor layer, and
wherein forming the light-scattering pattern includes performing a wet etching process on the mask pattern that remains on the exposed outer side surface of the lower portion.

26. A light-emitting device comprising:
a first semiconductor layer, an active layer and a second semiconductor layer sequentially disposed on one another; and
a passivation pattern disposed on outer surfaces of the first semiconductor layer, the active layer and the second semiconductor layer,
wherein the first semiconductor layer includes:
a first portion having a first width; and
a second portion disposed closer to the active layer than the first portion and having a second width larger than the first width.

27. The light-emitting device of claim 26, wherein the first portion is formed of a same material as the second portion and is integrated with the second portion.

28. The light-emitting device of claim 26, wherein the passivation pattern exposes an outer side surface of the first portion of the first semiconductor layer and covers the outer surfaces of the first semiconductor layer, the active layer and the second semiconductor layer.

29. The light-emitting device of claim 26, further comprising a light-scattering pattern disposed on an outer side surface of the first portion.

30. The light-emitting device of claim 26, wherein the active layer of the nitride semiconductor structure is disposed on one side of a top surface of the first semiconductor layer,
wherein the second semiconductor layer is disposed on the active layer,
wherein another side of the top surface opposite to the one side of the top surface of the first semiconductor layer is exposed.

31. The light-emitting device of claim 26, wherein side surfaces of the active layer and the second semiconductor layer of the nitride semiconductor structure are aligned with side surfaces of the second portion of the first semiconductor layer.

32. The light-emitting device of claim 26, wherein the passivation pattern includes a first open area exposing a portion of the first semiconductor layer and a second open area exposing a portion of the second semiconductor layer,
wherein the light-emitting device further comprises a first electrode and a second electrode, and
wherein the first electrode contacts the portion of the first semiconductor layer exposed through the first open area, and the second electrode contacts the portion of the second semiconductor layer exposed through the second open area.
